(19) United States
(12) Patent Application Publication
(10) Pub. No.: US 2026/0338860 A1
(43) Pub. Date: Oct. 29, 2026

(54) THREE-DIMENSIONAL INTEGRATED CIRCUIT, SEMICONDUCTOR DEVICE, AND OPERATION METHOD OF THREE-DIMENSIONAL INTEGRATED CIRCUIT INCLUDING PLURALITY OF SEMICONDUCTOR DIES

(71) Applicant: SAMSUNG ELECTRONICS CO., LTD., Suwon-si (KR)

(72) Inventors: Jiyoon SHIN, Suwon-si (KR); Changju LEE, Suwon-si (KR); Changkyu LEE, Suwon-si (KR); Jaeyoung BEOM, Suwon-si (KR)

(73) Assignee: SAMSUNG ELECTRONICS CO., LTD., Suwon-si (KR)

(21) Appl. No.: 19/656,250

(22) Filed: Apr. 23, 2026

(30) Foreign Application Priority Data
Apr. 24, 2025 (KR) 10-2025-0054111
Oct. 20, 2025 (KR) 10-2025-0151963

(51) Int. Cl. G01R 31/3177; H10W 90/00

(52) U.S. Cl. CPC G01R 31/3177; H10W 90/792

(57) ABSTRACT

A 3D integrated circuit including: a first semiconductor die including: a first logic circuit; and a first interface circuit; a second semiconductor die including: a second logic circuit; and a second interface circuit; and interconnects connected to the first semiconductor die and the second semiconductor die, wherein the first interface circuit includes: transmitting circuits connected to the interconnects; a first scan chain circuit outputting, during a first test period, first test data to the transmitting circuits; a first repair logic circuit configured to: set, based on defect information generated by a first test result from the first test data, a first repair path replacing a defective interconnect among the interconnects with a non-defective redundant interconnect; and output input data to the first scan chain circuit via the first repair path; and a second scan chain circuit outputting, during a second test period, second test data to the first repair path.

### CROSS-REFERENCE TO RELATED APPLICATION(S)

This application is based on and claims priority under 35 U.S.C. §119 to Korean Patent Application Nos. 10-2025-0054111, filed on Apr. 24, 2025, and 10-2025-0151963, filed on Oct. 20, 2025, in the Korean Intellectual Property Office, the disclosures of which are incorporated by reference herein in their entirety.

### BACKGROUND

The disclosure relates to a semiconductor device and a method of testing the 3D integrated circuit and the semiconductor device.

3D integrated circuits include a plurality of semiconductor dies (or integrated circuits) stacked on one another. The semiconductor dies in the 3D integrated circuits are electrically connected to each other via interconnects to perform communication. In 3D integrated circuits, process failure rates of interconnects are significantly higher than those on metal routing in single silicon. Therefore, a repair scheme may be utilized for interface circuits in semiconductor dies to detect defective interconnects by testing and replace the defective interconnects with redundant, non-defective interconnects.

### SUMMARY

The present disclosure may provide a three-dimensional (3D) integrated circuit, a semiconductor device, and a method of testing the 3D integrated circuit, capable of detecting defects in interconnects and defects in an entire signal path that includes a repair path for replacing a defective interconnect with a non-defective interconnect.

One or more embodiments of the present disclosure may provide a 3D integrated circuit including: a first semiconductor die including: a first logic circuit; and a first interface circuit; a second semiconductor die including: a second logic circuit; and a second interface circuit; and a plurality of interconnects connected between the first semiconductor die and the second semiconductor die, the plurality of interconnects being configured to transmit signals, wherein the first interface circuit includes: a plurality of transmitting circuits connected to the plurality of interconnects; a first scan chain circuit configured to output, during a first test period, first test data to the plurality of transmitting circuits; a first repair logic circuit configured to: set, based on defect information generated by a first test result from the first test data, a first repair path configured to replace a defective interconnect among the plurality of interconnects with a non-defective redundant interconnect; and output input data to the first scan chain circuit along the first repair path; and a second scan chain circuit configured to output, during a second test period, second test data to the first repair path.

One or more embodiments of the present disclosure may provide a semiconductor device including: a first semiconductor die including: a first interface circuit; and a first test controller; a second semiconductor die including: a second interface circuit; and a second test controller; and a plurality of interconnects connected to the first semiconductor die and the second semiconductor die, the plurality of interconnects being configured to transmit signals, wherein the first interface circuit includes: a first scan chain circuit configured to: receive first test data from the first test controller; and output the first test data; a first repair logic circuit configured to: set, based on a first test result from the first test data, a first repair path configured to replace a defective interconnect among the plurality of interconnects using a non-defective redundant interconnect; and a second scan chain circuit configured to: receive second test data from the first test controller; detect, based on the second test data, a defect in a signal path; and output the second test data, wherein the signal path includes: the first repair path; the first scan chain circuit; and interconnects corresponding to the first repair path among the plurality of interconnects.

One or more embodiments of the present disclosure may provide a 3D integrated circuit including a first semiconductor die and a second semiconductor die connected to each other by a plurality of interconnects, the method including: performing a first test by transmitting, via a first test path including the plurality of interconnects, first test data from a first scan chain circuit of the first semiconductor die to a second scan chain circuit of the second semiconductor die; setting, based on defect information generated by results of the first test, a repair path that includes: a first repair logic circuit of the first semiconductor die; and a second repair logic circuit of the second semiconductor die, wherein the repair path is configured to replace a defective interconnect among the plurality of interconnects with a non-defective redundant interconnect; and performing a second test by transmitting, via a second test path including the repair path and interconnects corresponding to the repair path among the plurality of interconnects, second test data from a third scan chain circuit of the first semiconductor die to a fourth scan chain circuit of the second semiconductor die.

### BRIEF DESCRIPTION OF DRAWINGS

Embodiments will be more clearly understood from the following detailed description taken in conjunction with the accompanying drawings in which:

FIG. 1 is a block diagram showing a semiconductor device according to one or more embodiments;

FIGS. 2A to 2C are diagrams illustrating interconnects according to embodiments;

FIG. 3 is a block diagram showing a semiconductor device according to one or more embodiments;

FIG. 4 is a block diagram illustrating a test operation of a semiconductor device according to one or more embodiments, FIG. 5A illustrates a first test path of a semiconductor device according to one or more embodiments, and FIG. 5B illustrates a second test path of a semiconductor device according to one or more embodiments;

FIG. 6 shows a data path during normal operation of a semiconductor device according to one or more embodiments;

FIGS. 7A to 7G sequentially illustrate a test method of a semiconductor device, according to one or more embodiments;

FIGS. 8A and 8B illustrate examples of a first repair logic and a second repair logic provided in a semiconductor device according to one or more embodiments;

FIGS. 9A and 9B illustrate a test method for a semiconductor device according to a comparative example;

FIG. 10 is a block diagram showing a semiconductor device according to one or more embodiments;

FIG. 11 is a block diagram showing a semiconductor device according to one or more embodiments;

FIG. 12 is a block diagram showing a semiconductor device according to one or more embodiments;

FIGS. 13A, 13B, 13C, and 13D are structural diagrams illustrating semiconductor devices according to embodiments; and

FIG. 14 is a structural diagram illustrating an example of an electronic system according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

The embodiments of the disclosure described in the present specification and the drawings are only presented as specific examples to easily explain the technical content according to the embodiments of the disclosure and help understanding of the embodiments of the disclosure, not intended to limit the scope of the embodiments of the disclosure. Therefore, the scope of one or more embodiments of the disclosure should be construed as encompassing all changes or modifications derived from the technical spirit of one or more embodiments of the disclosure in addition to the embodiments disclosed herein.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, “about the same”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

Unless otherwise indicated, as used herein with regard to any plurality of a particular type of component, any two components of that type are considered “adjacent” or “adjacent to” one another so long as no other component of that type occupies a space between the two components. That is, the two components are considered adjacent each other if the two components are not separated from each other by an intervening component of that type.

Furthermore, although one or more embodiments may comprise the disclosed features as described herein—as well as additional features not specifically described—other embodiments may instead be completely free of non-disclosed elements. For example, non-disclosed elements may be completely omitted from one or more embodiments of the present disclosure.

As used herein with references to drawings, illustrations, graphs and/or any other graphical depiction, the term “plan view” may refer to an orthographic projection of at least part of a surface, region, object, structure, and/or any other feature, the orthographic projection being from a position of a plane that is coplanar with or intersects at least part of the feature. For example, a “plan view” (also referred to as “top-down view”, or a “top view”) may be a sectional view that is taken from above one or more features. In such a plan view, portion(s) of one or more features that is/are located above the plane depicted in the plan view may be omitted to better illustrate part of one or more features located below the plane.

As used herein, the terms “front (or forward)”, “rear (or back, backward, rearward)”, “up (or upper, top, above)”, “down (or lower, bottom, below)”, “left”, “right”, and the like may be defined with reference to the drawings, and may not be intended to limit the shape and/or position of each component.

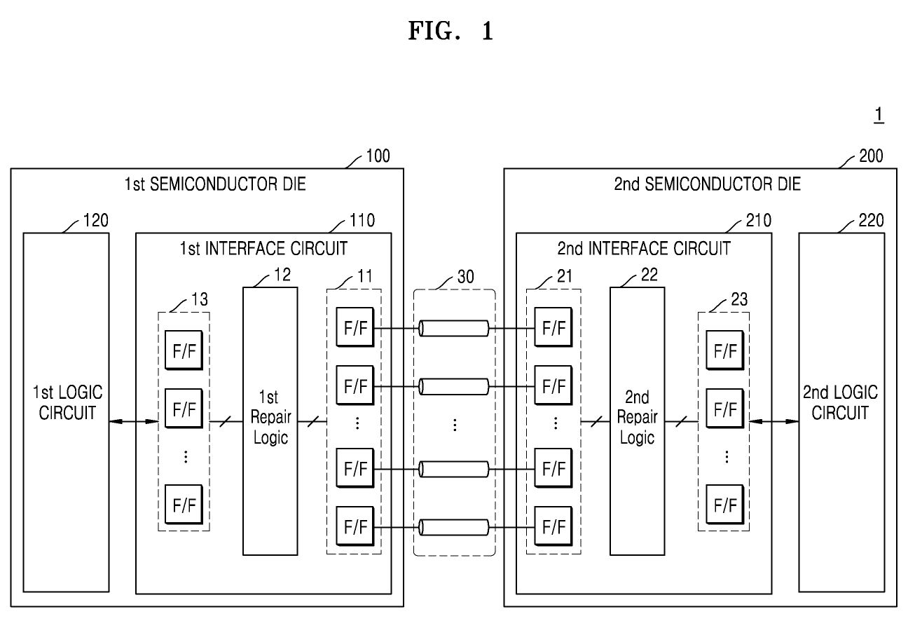

FIG. 1 is a block diagram showing a semiconductor device 1 according to one or more embodiments.

Referring to FIG. 1, the semiconductor device 1 may include a first semiconductor die 100, a second semiconductor die 200, and a plurality of interconnects 30. In one or more embodiments, the first semiconductor die 100 and the second semiconductor die 200 may be stacked in a vertical direction, and thus, the semiconductor device 1 may be referred to as a three-dimensional (3D) integrated circuit.

The first and second semiconductor dies 100 and 200 may include integrated circuits for performing certain functions, and may be referred to as logic dies, memory dies, analog dies, or the like depending on the functions thereof. The first semiconductor die 100 may perform functions identical to or different from those of the second semiconductor die 200. For example, when the first and second semiconductor dies 100 and 200 are implemented as logic dies, a central processing unit (CPU), a graphics processing unit (GPU), a neural processing unit (NPU)/artificial intelligence (AI) accelerator, a digital signal processor (DSP), a power management integrated circuit (PMIC), a memory controller, an I/O interface circuit, a security circuit, and on-chip memory may be implemented in the first semiconductor die 100 and/or the second semiconductor die 200.

The first and second semiconductor dies 100 and 200 may be formed on silicon, silicon on insulator, or a compound semiconductor substrate. The first and second semiconductor dies 100 and 200 may include a plurality of active elements and a plurality of passive devices, and each of the elements may be wired via a metal layer.

Depending on manufacturing process methods of the semiconductor device 1, a manufacturing process of forming the first semiconductor die 100 may be the same as or different from a manufacturing process of forming the second semiconductor die 200. The first and second semiconductor dies 100 and 200 may be stacked on one another in a vertical direction based on a die-to-die stacking method, a die-to-wafer stacking method, or a wafer-to-wafer stacking method.

A plurality of interconnects 30 may include structures for transmitting electrical signals between the first semiconductor die 100 and the second semiconductor die 200, and may be implemented as through-silicon vias (TSVs), micro bumps, or hybrid bonds (e.g., bonding pads).

The plurality of interconnects 30 may include more interconnects than the number of signals (data) transmitted and received in parallel between the first semiconductor die 100 and the second semiconductor die 200 during a normal operation of the semiconductor device 1. For example, when n signals (where n is an integer greater than or equal to 2) are transmitted and received in parallel (or simultaneously) between the first semiconductor die 100 and the second semiconductor die 200, the plurality of interconnects 30 may include m interconnects (where m is an integer greater than n), which includes n interconnects (hereinafter referred to as normal interconnects) and one or more redundant interconnects. Herein, a normal interconnect refers to an interconnect that is fundamentally configured to transmit signals unless there is a defect in the interconnect itself. A redundant interconnect refers to an interconnect that is provided to directly or indirectly (e.g., in a roundabout manner) replace a defective normal interconnect among the interconnects. Hereinafter, in this disclosure, “replace” may mean either direct replacement or indirect replacement.

During the manufacturing process of the semiconductor device 1, the plurality of interconnects 30 are subjected to numerous stress conditions, and various types of defects may occur in the plurality of interconnects 30. For example, cracks may be formed in materials around a TSV, causing a short circuit between the TSV and a neighboring electrode, or voids may be formed in the interconnect during a bonding process. Defective interconnects may fail to transmit signals properly, and thus, the reliability of all circuit operations may be degraded. Accordingly, a repair scheme may be utilized, whereby a non-defective redundant interconnect replaces the defective normal interconnect.

The first semiconductor die 100 may include a first interface circuit 110 and a first logic circuit 120, and the second semiconductor die 200 may include a second interface circuit 210 and a second logic circuit 220. The first logic circuit 120 is a circuit that performs data processing operations, such as computation, control, or determination, corresponding to certain functions supported by the first semiconductor die 100, and may include at least one of an arithmetic logic circuit, a control circuit, a register, a multiplexer, a sequential logic circuit, and a combinational logic circuit. The second logic circuit 220 is a circuit that performs data processing operations, such as computation, control, and determination, corresponding to certain functions supported by the second semiconductor die 200, and may include at least one of an arithmetic logic circuit, a control circuit, a register, a multiplexer, a sequential logic circuit, and a combinational logic circuit. In one or more embodiments, the first and second logic circuits 120 and 220 may be defined broadly as the remainder or a portion thereof, excluding the first and second interface circuits 110 and 210, in the first and second semiconductor dies 100 and 200 respectively.

The first interface circuit 110 and the second interface circuit 210 may be configured to transmit and receive various signals between the first semiconductor die 100 and the second semiconductor die 200.

During a normal operating mode (or a normal operating period, also referred to as a “non-test” mode, or “non-test” period), the first interface circuit 110 and the second interface circuit 210 may transmit and receive signals (e.g., operating data) between the first logic circuit 120 and the second logic circuit 220.

During a test mode (or a test period), the first interface circuit 110 and the second interface circuit 210 may be used to test whether defects occur in the plurality of interconnects 30, and also to test whether signals are transmitted and received properly between the first interface circuit 110 and the second interface circuit 210. For example, during a manufacturing stage of the semiconductor device 1, the test may be performed.

In the normal operating mode, the first interface circuit 110 and the second interface circuit 210 operate based on a first clock signal (e.g., a functional clock signal). In the test mode, the first interface circuit 110 and the second interface circuit 210 operate based on a second clock signal (a test clock signal). The frequency of the first clock signal may differ from the frequency of the second clock signal. For example, the frequency of the first clock signal may be higher than the frequency of the second clock signal.

The first interface circuit 110 may include a first scan chain 11 (e.g., a first scan chain circuit), a first repair logic 12 (e.g., a first repair logic circuit), and a second scan chain 13 (e.g., a second scan chain circuit). In one or more embodiments, the first scan chain 11 may be located adjacent to the boundary of the first semiconductor die 100 near the plurality of interconnects 30, the first repair logic 12 may be connected between the first scan chain 11 and the second scan chain 13, and the second scan chain 13 may be electrically connected to the first logic circuit 120. Herein, any “scan chain” or “repair logic” may be understood as comprising an electrical circuit and/or electrical circuitry.

The first scan chain 11 and the second scan chain 13 may each include a plurality of flip-flops F/F. The plurality of flip-flops F/F may each temporarily store and output 1-bit data. The plurality of flip-flops F/F may be connected to each other in series to receive data sequentially or simultaneously, and temporarily store and then output the data. The flip-flops F/F may be replaced by other storage elements, such as a latch and a register, and the flip-flops F/F or other storage elements may be referred to as scan cells.

The number of flip-flops F/F in the first scan chain 11 may be greater than the number of flip-flops F/F in the second scan chain 13. For example, the first scan chain 11 may include the plurality of flip-flops F/F (e.g., m flip-flops F/F) equal to the number of interconnects 30, and the second scan chain 13 may include the plurality of flip-flops F/F (e.g., n flip-flops F/F) equal to the number of signals transmitted and received in parallel between the first semiconductor die 100 and the second semiconductor die 200.

The first scan chain 11 may be used for a first test of detecting a defective interconnect among the plurality of interconnects 30. Based on defect information generated according to test results of the first test, the first repair logic 12 may perform repair by routing a signal path (specifically referred to as a repair path) between the first scan chain 11 and the second scan chain 13. According to the repair path set in the first repair logic 12, a non-defective redundant interconnect among the plurality of interconnects 30 may replace the defective normal interconnect. After the repair is performed (e.g., after the repair path is set in the first repair logic 12), the second scan chain 13 may be used for a second test of detecting whether a defect occurs in the entire signal path (or data path) including the first repair logic 12, the first scan chain 11, and the plurality of interconnects 30.

The second interface circuit 210 may have a symmetric structure with respect to the first interface circuit 110. The second interface circuit 210 may include a third scan chain 21, a second repair logic 22, and a fourth scan chain 23.

In one or more embodiments, the third scan chain 21 may be located adjacent to the boundary of the second semiconductor die 200 near the plurality of interconnects 30, the second repair logic 22 may be connected between the third scan chain 21 and the fourth scan chain 23, and the fourth scan chain 23 may be electrically connected to the second logic circuit 220.

The third scan chain 21 and the fourth scan chain 23 may each include a plurality of flip-flops F/F, and the number of flip-flops F/F in the third scan chain 21 may be greater than the number of flip-flops F/F in the fourth scan chain 23. For example, the number of flip-flops F/F in the third scan chain 21 may be equal to the number of flip-flops F/F in the first scan chain 11, and the number of flip-flops F/F in the fourth scan chain 23 may be equal to the number of flip-flops F/F in the second scan chain 13.

The third scan chain 21 may be used for the first test of detecting a defective interconnect among the plurality of interconnects 30. The first test may be performed by transmission of first test data via a first test path that includes the first scan chain 11, the plurality of interconnects 30, and the third scan chain 21.

Based on the defect information generated according to the test results of the first test, the second repair logic 22 may perform repair by routing a repair path between the third scan chain 21 and the fourth scan chain 23.

After the repair path is set in the second repair logic 22, the fourth scan chain 23 may be used for a second test of detecting a defect in the entire signal path that includes the plurality of interconnects 30, the third scan chain 21, and the second repair logic 22.

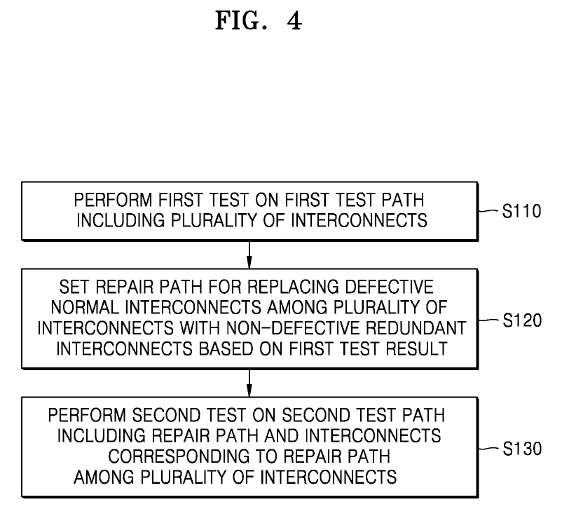

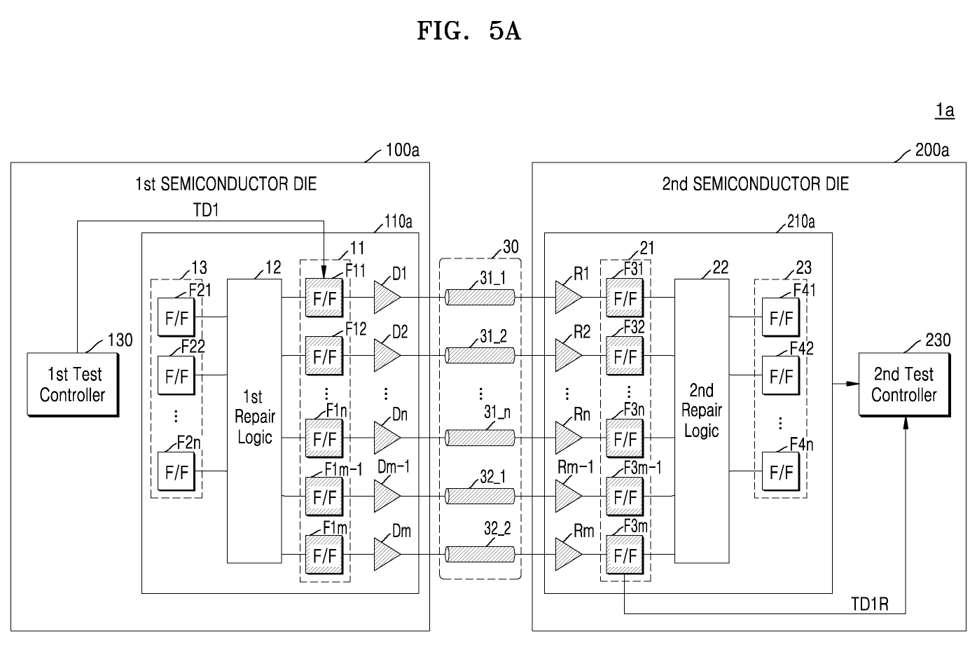

Thus, in the test mode of the semiconductor device 1, prior to performing the repair, the first test for detecting the defects in the plurality of interconnects 30 may be performed by using the first scan chain 11 and the third scan chain 21. Also, the first repair logic 12 and the second repair logic 22 may perform the repair based on the defect information generated according to the test results of the first test. In addition, after performing the repair, the second test for detecting defects in the entire signal path may be performed by using the second scan chain 13 and the fourth scan chain 23. The first test may be referred to as the pre-repair test, and the second test may be referred to as the post-repair test. The first test, the repair, and the second test are described below in more detail with reference to FIGS. 4-7G.

As described above, the semiconductor device 1 according to one or more embodiments may perform the first test of detecting defects present in the plurality of interconnects 30. The first test may be performed without the influence of the internal logics (e.g., the first and second repair logics 12 and 22) of the first interface circuit 110 and the second interface circuit 210, and thus, it may be accurately detected whether a defect occurs in the plurality of interconnects 30. Furthermore, since it may also be detected whether a defect occurs in the redundant interconnects, testability may be improved.

Furthermore, the semiconductor device 1 according to one or more embodiments may perform the second test for detecting whether a defect occurs in the entire signal path that includes not only the plurality of interconnects 30 but also the first and second repair logics 12 and 22. Accordingly, the test coverage is expanded, and the operational reliability of the entire signal path, including repair paths, may be verified.

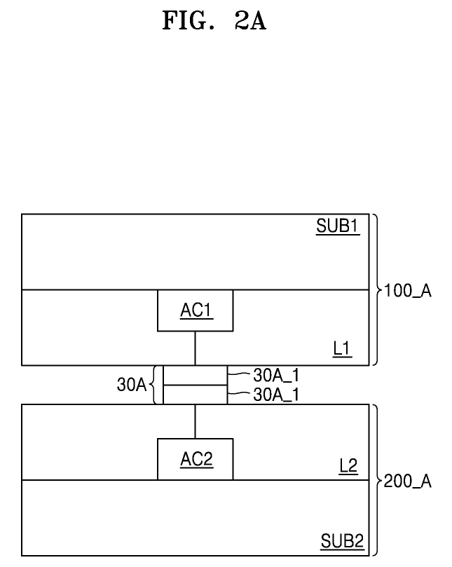

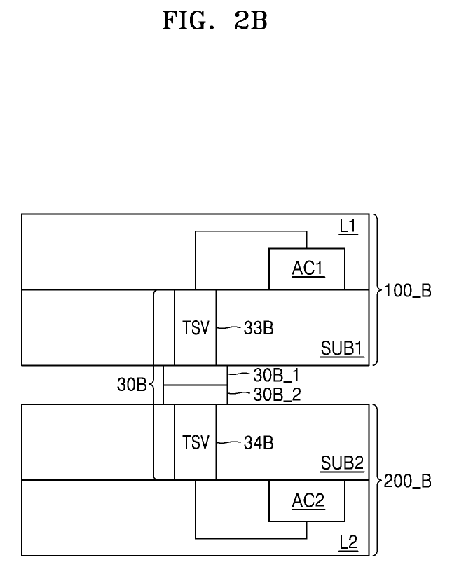

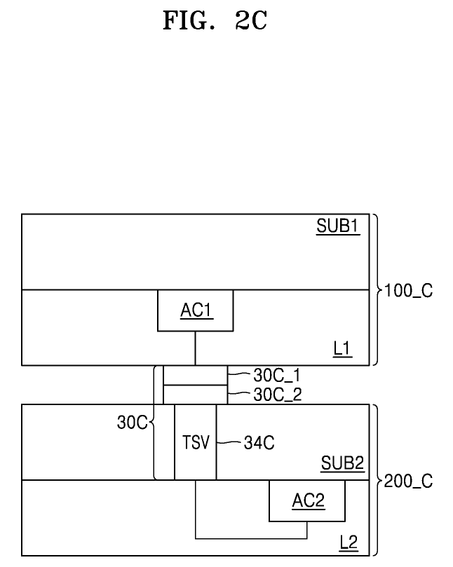

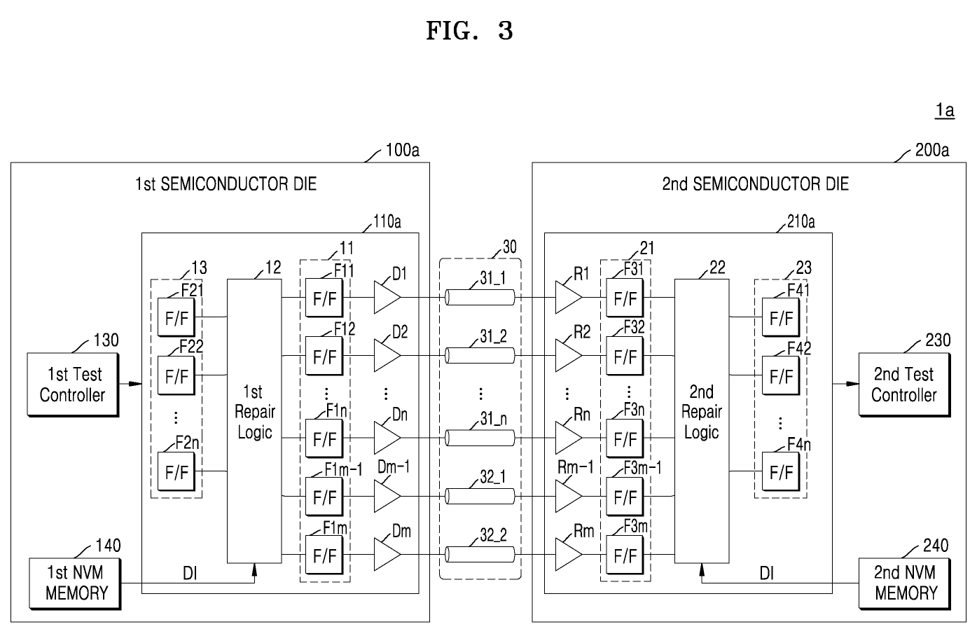

FIGS. 2A to 2C are diagrams illustrating interconnects according to embodiments.

Referring to FIG. 2A, first and second semiconductor dies 100_A and 200_A may be vertically stacked. The first semiconductor die 100_A may include a substrate SUB1 and a layer L1 formed by a back end of line (BEOL), and the layer L1 may include an active element AC1 (e.g., a transistor, a diode, an optical device, or the like) formed by a front end of line (FEOL). The second semiconductor die 200_A may include a substrate SUB2 and a layer L2 formed by the BEOL, and the layer L2 may include an active element AC2 formed by the FEOL.

The first semiconductor die 100_A and the second semiconductor die 200_A may be stacked in a face-to-face (F2F) configuration. Specifically, a bonding pad 30A_1 connected to the active element AC1 may be formed on the upper end of layer L1 of the first semiconductor die 100_A, and a bonding pad 30A_2 connected to the active element AC2 may be formed on the upper end of layer L2 of the second semiconductor die 200_A. Then, the bonding pads 30A_1 and 30A_2 may be bonded to each other. Accordingly, an interconnect 30A may include the bonding pads 30A_1 and 30A_2.

Referring to FIG. 2B, a first semiconductor die 100_B may include a substrate SUB1 having a through-silicon via (TSV) 33B and a layer L1 having an active element AC1 connected to the TSV 33B. A second semiconductor die 200_B may include a substrate SUB2 having a TSV 34B and a layer L2 having an active element AC2 connected to the TSV 34B.

The first semiconductor die 100_B and the second semiconductor die 200_B may be stacked in a back-to-back (B2B) configuration. A bonding pad 30B_1 connected to the TSV 33B may be formed on the upper end of the substrate SUB1 of the first semiconductor die 100_B, and a bonding pad 30B_2 connected to the TSV 34B may be formed on the upper end of the substrate SUB2 of the second semiconductor die 200_B. Then, the bonding pads 30B_1 and 3B_2 may be bonded to each other. Accordingly, an interconnect 30B may include the bonding pads 30B_1 and 30B_2 and the TSVs 33B and 34B.

Referring to FIG. 2C, a first semiconductor die 100_C may include a substrate SUB1 and a layer L1 having an active element AC1. A second semiconductor die 200_C may include a substrate SUB2 having a TSV 34C and a layer L2 having an active element AC2 connected to the TSV 34C.

The first semiconductor die 100_C and the second semiconductor die 200_C may be stacked in a face-to-back (F2B) configuration. A bonding pad 30C_1 connected to the active element AC1 may be formed on the upper end of layer L1 of the first semiconductor die 100_C, and a bonding pad 30C_2 connected to the TSV 34C may be formed on the upper end of the substrate SUB2 of the second semiconductor die 200_C. Then the bonding pads 30C_1 and 30C_2 may be bonded to each other. Accordingly, an interconnect 30C may include the bonding pads 30C_1 and 30C_2 and the TSV 34C.

However, the interconnects 30A, 30B, and 30C shown in FIGS. 2A to 2C are only examples, and the embodiment is not limited thereto. The interconnects according to the disclosure may be implemented in various other forms.

FIG. 3 is a block diagram showing a semiconductor device 1a according to one or more embodiments.

Referring to FIG. 3, the semiconductor device 1a may include a first semiconductor die 100a, a second semiconductor die 200a, and the plurality of interconnects 30. The plurality of interconnects 30 may include first to nth normal interconnects 31_1 to 31_n and redundant interconnects 32_1 and 32_2. For convenience of description, FIG. 3 shows that the redundant interconnects 32_1 and 32_2 are arranged on one side of the first to nth normal interconnects 31_1 to 31_n, and the redundant interconnects 32_1 and 32_2 are adjacent to each other, but the embodiment is not limited thereto. The redundant interconnects 32_1 and 32_2 may be arranged respectively on both sides of the first to nth normal interconnects 31_1 to 31_n or may be arranged between the first to nth normal interconnects 31_1 to 31_n, and the redundant interconnects 32_1 and 32_2 may not be adjacent to each other.

The first semiconductor die 100a may include a first interface circuit 110a, a first test controller 130, and a first non-volatile memory 140. The second semiconductor die 200a may include a second interface circuit 210a, a second test controller 230, and a second non-volatile memory 240. The first and second semiconductor dies 100a and 200a further include the first logic circuit 120 (see FIG. 1) and the second logic circuit 220 (see FIG. 1), respectively.

In the embodiment, the first interface circuit 110a may transmit signals (data) to the second interface circuit 210a, and the second interface circuit 210a may receive data from the first interface circuit 110a.

The first interface circuit 110a may include the first scan chain 11, the first repair logic 12, the second scan chain 13, and a plurality of transmitting circuits, for example, first to mth transmitting circuits D1 to Dm.

The first to mth transmitting circuits D1 to Dm may include first to nth transmitting circuits and redundant transmitting circuits and may also be hereinafter referred to as first to nth transmitting circuits D1 to Dn and redundant transmitting circuits Dm-1 and Dm. In one or more embodiments, the number of redundant transmitting circuits Dm-1 and Dm may be equal to the number of redundant interconnects 32_1 and 32_2.

The first to mth transmitting circuits D1 to Dm may transmit input signals to corresponding interconnects among the plurality of interconnects 30. In one or more embodiments, the first to mth transmitting circuits D1 to Dm may be implemented as transmit buffers.

In one or more embodiments, the first to mth transmitting circuits D1 to Dm may be connected to the plurality of interconnects 30 in one-to-one correspondence, and each may transmit (or output) an input signal to a corresponding one of the plurality of interconnects 30. For example, the first to nth transmitting circuits D1 to Dn may be connected to the first to nth normal interconnects 31_1 to 31_n in one-to-one correspondence, and the redundant transmitting circuits Dm-1 and Dm may be connected to the redundant interconnects 32_1 and 32_2 in one-to-one correspondence.

The first scan chain 11 may include a plurality of first flip-flops F11 to F1m, and the number of first flip-flops F11 to F1m may be m. The plurality of first flip-flops F11 to F1m may include n first flip-flops and first redundant flip-flops and may also be hereinafter referred to as n first flip-flops F11 to F1n and first redundant flip-flops F1m-1 and F1m. In one or more embodiments, the number of first redundant flip-flops F1m-1 and F1m may be equal to the number of redundant transmitting circuits Dm-1 and Dm. The plurality of first flip-flops F11 to F1m may be connected to the first to mth transmitting circuits D1 to Dm in one-to-one correspondence. The plurality of first flip-flops F11 to F1m may temporarily store received data and then output the data to the first to mth transmitting circuits D1 to Dm.

The second scan chain 13 may include a plurality of second flip-flops F21 to F2n, and the number of second flip-flops F21 to F2n may be n. The number of second flip-flops F21 to F2nmay be less than the number of first flip-flops F11 to F1m. The plurality of second flip-flops F21 to F2n may temporarily store received data and then output the data to the first repair logic 12.

The first repair logic 12 may output the data received from the second scan chain 13 to the first scan chain 11. The first repair logic 12 may route signal paths between the first scan chain 11 and the second scan chain 13, and may output pieces of data (e.g., n-bit data) received from the plurality of second flip-flops F21 to F2n of the second scan chain 13 to the corresponding n first flip-flops among the plurality of first flip-flops F11 to F1m of the first scan chain 11.

For example, the first repair logic 12 may be implemented as one or more multiplexers (or demultiplexers), and based on a first selection signal, the multiplexer may select n first flip-flops, to which the pieces of data are to be transmitted, from among the plurality of first flip-flops F11 to F1m in the first scan chain 11.

The second interface circuit 210a may include a plurality of receiving circuits, for example, first to mth receiving circuits R1 to Rm, the third scan chain 21, the second repair logic 22, and the fourth scan chain 23.

The first to mth receiving circuits R1 to Rm may include first to nth receiving circuits and redundant receiving circuits and may also be hereinafter referred to as first to nth receiving circuits R1 to Rn and redundant receiving circuits Rm-1 and Rm. In one or more embodiments, the number of redundant receiving circuits Rm-1 and Rm may be equal to the number of redundant interconnects 32_1 and 32_2.

The first to mth receiving circuits R1 to Rm may receive signals from corresponding interconnects among the plurality of interconnects 30. In one or more embodiments, the first to mth receiving circuits R1 to Rm may be implemented as receive buffers.

In one or more embodiments, the first to mth receiving circuits R1 to Rm may be connected to the plurality of interconnects 30 in one-to-one correspondence, and each may receive data transmitted (or output) from a corresponding one of the plurality of interconnects 30. For example, the first to nth receiving circuits R1 to Rn may be connected to the first to nth normal interconnects 31_1 to 31_n in one-to-one correspondence, and the redundant receiving circuits Rm-1 and Rm may be connected to the redundant interconnects 32_1 and 32_2 in one-to-one correspondence.

The third scan chain 21 may include a plurality of third flip-flops F31 to F3m, and the number of third flip-flops F31 to F3m may be m. The plurality of third flip-flops F31 to F3m may include n third flip-flops and third redundant flip-flops and may also be hereinafter referred to as n third flip-flops F31 to F3n and third redundant flip-flops F3m-1 and F3m. In one or more embodiments, the number of third redundant flip-flops F3m-1 and F3m may be equal to the number of redundant receiving circuits Rm-1 and Rm. The plurality of third flip-flops F31 to F3m may be connected to the first to mth receiving circuits R1 to Rm in one-to-one correspondence. The plurality of third flip-flops F31 to F3m may temporarily store pieces of data received from the first to mth receiving circuits R1 to Rm, respectively, and then output the data to the second repair logic 22.

The fourth scan chain 23 may include a plurality of fourth flip-flops F41 to F4n, and the number of the fourth flip-flops F41 to F4n may be n. The number of fourth flip-flops F41 to F4n may be less than the number of plurality of third flip-flops F31 to F3m. The plurality of fourth flip-flops F41 to F4n may temporarily store data received from the second repair logic 22 and then output the data.

The second repair logic 22 may output the data received from the third scan chain 21 to the fourth scan chain 23. The second repair logic 22 may route signal paths between the third scan chain 21 and the fourth scan chain 23, and may output, to the plurality of fourth flip-flops F41 to F4n, pieces of data (e.g., n-bit data) received from n third flip-flops, corresponding to the plurality of fourth flip-flops F41 to F4n, from among the plurality of third flip-flops F31 to F3m of the third scan chain 21.

For example, the second repair logic 22 may be implemented as one or more multiplexers (or demultiplexers), and based on a second selection signal, the multiplexer may select n third flip-flops, which are to receive data, from among the plurality of third flip-flops F31 to F3m in the third scan chain 21.

The first test controller 130 and the second test controller 230 may perform tests in a test mode. The first test controller 130 may provide test data to the first interface circuit 110a, and the test data (or transformed data generated based on the test data) may be transmitted from the first interface circuit 110a to the second interface circuit 210a via the plurality of interconnects 30. The second test controller 230 may receive test data (or transformed data) from the second interface circuit 210a and generate (or analyze) test results by comparing the received test data to comparison data (e.g., a golden reference value or an expected value).

As described with reference to FIG. 1, the first test and the second test may be performed. Based on the test results of the first test, the second test controller 230 may detect defective interconnects among the plurality of interconnects 30, for example, the first to nth normal interconnects 31_1 to 31_n and the redundant interconnects 32_1 and 32_2, and may generate defect information representing the defective interconnects. The first test controller 130 and the second test controller 230 may share the defect information. Subsequently, the first repair logic 12 and the second repair logic 22 may set a repair path based on the defect information, and the second test may be performed on the entire signal path (e.g., the second test path) including the repair path. Also, based on the test results of the second test, the second test controller 230 may detect whether a defect occurs in the entire signal path.

The first non-volatile memory 140 and the second non-volatile memory 240 may store the defect information. In one or more embodiments, the first non-volatile memory 140 and the second non-volatile memory 240 may be implemented as one time programmable (OTP) memory, and the defect information may be stored therein by OTP fusing. However, the embodiment is not limited thereto, and the first non-volatile memory 140 and the second non-volatile memory 240 may be implemented as flash memory, ferroelectric random-access memory (FeRAM), magnetoresistive RAM (MRAM), resistive RAM (ReRAM), phase-change memory (PCM), or the like.

In the embodiment described herein, the first semiconductor die 100a operates as a driver for transmitting signals to the second semiconductor die 200a, and the second semiconductor die 200a operates as a receiver for receiving signals from the first semiconductor die 100a. However, the embodiment is not limited thereto, and the second semiconductor die 200a may operate as a driver while the first semiconductor die 100a operates as a receiver. Alternatively, the first and second semiconductor dies 100a and 200a may each operate as both a driver and a receiver for communicating signals with each other.

FIG. 4 is a block diagram illustrating a test operation of a semiconductor device according to one or more embodiments. FIG. 5A illustrates the first test path of the semiconductor device 1a according to one or more embodiments and FIG. 5B illustrates the second test path of the semiconductor device 1a according to one or more embodiments.

The test operation of the semiconductor device 1a may be performed during the manufacturing process and may be performed in the first interface circuit 110a and the second interface circuit 210a under control by the first test controller 130 and the second test controller 230, respectively.

Referring to FIGS. 4 and 5A, the semiconductor device 1a may perform the first test on the first test path, which includes the plurality of interconnects 30, during the first test period (S110). In FIG. 5A, elements marked with hatching may be included in the first test path.

The first test controller 130 may provide first test data TD1 to the first scan chain 11 of the first interface circuit 110a. The first test data TD1 may be transmitted from the first scan chain 11 to the third scan chain 21 via the first to mth transmitting circuits D1 to Dm (or hereinafter referred to as the plurality of transmitting circuits D1 to Dm) the plurality of interconnects 30, and the first to mth receiving circuits R1 to Rm (or hereinafter referred to as the plurality of receiving circuits R1 to Rm). The third scan chain 21 may transmit first received test data TD1R to the second test controller 230.

The second test controller 230 may generate a first test result (the test result of the first test) by comparing the first received test data TD1R to first comparison data. The first comparison data may be the same data as the first test data TD1 or data predicted based on the first test data TD1. When there is no defect in the first test path, specifically in the plurality of interconnects 30, the first received test data TD1R may be the same as the first comparison data. When there is a defect in the first test path, specifically in any one of the plurality of interconnects 30, the first received test data TD1R may be different from the first comparison data.

In one or more embodiments, the first test data TD1, the first received test data TD1R, and the first comparison data may each include a number of bits equal to the number of interconnects 30 (e.g., m). The second test controller 230 may compare the m bits of the first received test data TD1R to the m bits of the first comparison data bit by bit, thereby identifying a defective (failed) interconnect among the plurality of interconnects 30. The second test controller 230 may detect which bit(s) among the m bits differ in bit value (e.g., one of ‘0’ and ‘1’) between the first received test data TD1R and the first comparison data, and may determine that the interconnect, corresponding to the bit for which the bit values differ from each other between the first received test data TD1R and the first comparison data, is defective.

For example, when the bit values of the bits received via the nth normal interconnect 31_n and the redundant interconnect 32_2 among the m bits of the first received test data TD1R are different from the bit values of the corresponding bits of the first comparison data, the second test controller 230 may determine that the nth normal interconnect 31_n and the redundant interconnect 32_2 are defective.

The second test controller 230 may generate defect information that represents defective interconnects among the plurality of interconnects 30.

The semiconductor device 1a may set a repair path for replacing defective interconnects among the plurality of interconnects 30 with non-defective redundant interconnects based on the first test result (S120). The first repair logic 12 and the second repair logic 22 may set the repair path based on the defect information. The first repair logic 12 may set a first repair path by setting the connection relationships between the plurality of second flip-flops F21 to F2n of the second scan chain 13 and the plurality of first flip-flops F11 to F1m of the first scan chain 11 based on the defect information. The second repair logic 22 may set a second repair path by setting the connection relationships between the plurality of third flip-flops F31 to F3m of the third scan chain 21 and the plurality of fourth flip-flops F41 to F4n of the fourth scan chain 23 based on the defect information.

For example, when the nth normal interconnect 31_n is defective, the first repair logic 12 and the second repair logic 22 may set the repair path to replace the nth normal interconnect 31_n by using the redundant interconnects 32_1 and 32_2. When the redundant interconnect 32_2 is defective, the first repair logic 12 and the second repair logic 22 may set the repair path such that the non-defective redundant interconnect 32_1 replaces the defective nth normal interconnect 31_n.

Referring to FIGS. 4 and 5B, the semiconductor device 1a may perform the second test on the second test path, which includes the repair path and the interconnects corresponding to the repair path among the plurality of interconnects 30, during the second test period (S130). In FIG. 5B, elements marked with hatching may be included in the second test path.

The first test controller 130 may provide second test data TD2 to the second scan chain 13 of the first interface circuit 110a. The second test data TD2 may be transmitted from the second scan chain 13 to the fourth scan chain 23 via the first repair logic 12, the first scan chain 11, the plurality of transmitting circuits D1 to Dm, the plurality of interconnects 30, the plurality of receiving circuits R1 to Rm, the third scan chain 21, and the second repair logic 22. The fourth scan chain 23 may transmit second received test data TD2R to the second test controller 230.

Specifically, the second test data TD2 may be transmitted from the second scan chain 13 to the fourth scan chain 23 via the repair paths of the first repair logic 12 and the second repair logic 22 and the elements (e.g., the elements marked with hatching in FIG. 5B) corresponding to the repair paths among the first scan chain 11, the plurality of transmitting circuits D1 to Dm, the plurality of interconnects 30, and the plurality of receiving circuits R1 to Rm, and the third scan chain 21. The defective nth normal interconnect 31_n and elements corresponding thereto are excluded from transmission of the second test data TD2. In other words, the second test is not performed on the defective nth normal interconnect 31_n and the elements corresponding thereto.

The second test controller 230 may generate a second test result (the test result of the second test) by comparing the second received test data TD2R to second comparison data. The second comparison data may be the same data as the second test data TD2 or data predicted based on the second test data TD2. When there is no defect in the second test path, the second received test data TD2R may be the same as the second comparison data. When there is a defect in the second test path, the second received test data TD2R may be different from the second comparison data. Based on the comparison results, the second test controller 230 may determine whether a defect exists in the second test path. Accordingly, it may be tested whether the first and second repair logics 12 and 22, to which the repair paths are applied, and the plurality of interconnects 30 operate normally, and thus, it may be confirmed whether the first and second interface circuits 110a and 210a operate stably.

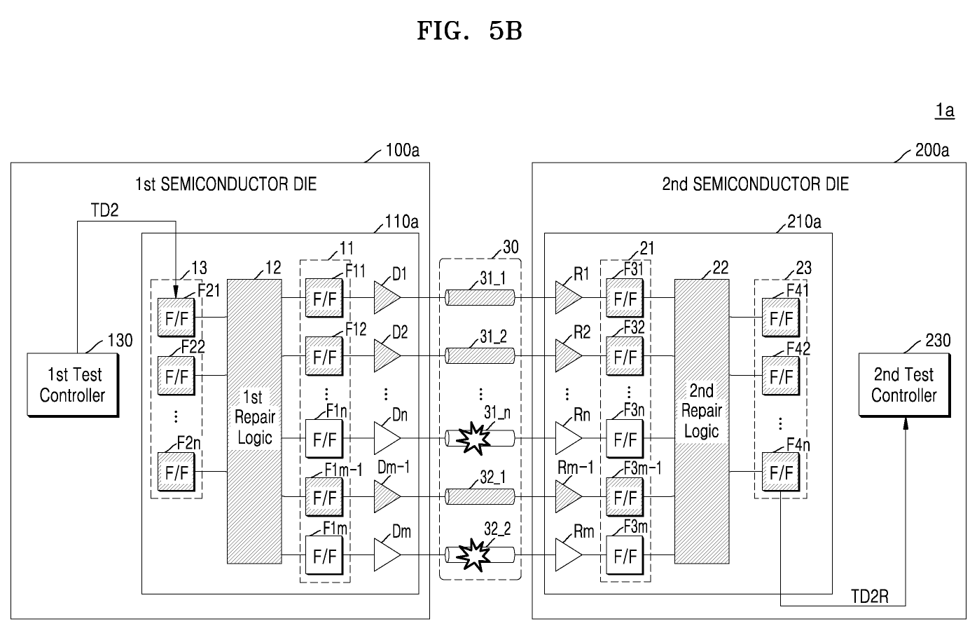

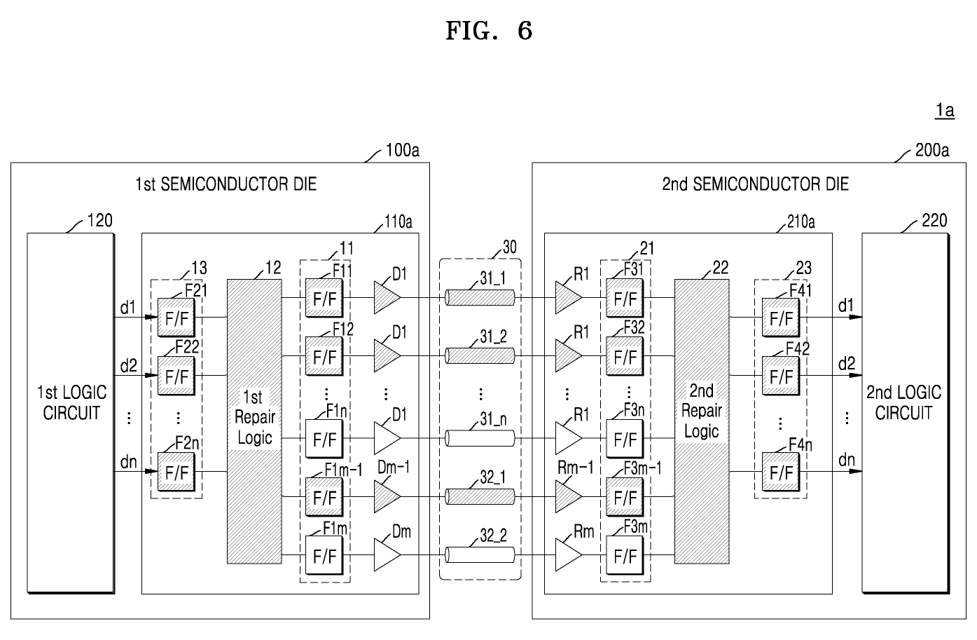

FIG. 6 shows a data path during a normal operation of the semiconductor device 1a according to one or more embodiments.

When there is no defect in the second test path according to the second test results described with reference to FIGS. 4 and 5B, the second test path may be used as a data path during the normal operation of the semiconductor device 1a.

Referring to FIG. 6, during the normal operation of the semiconductor device 1a, the first interface circuit 110a of the first semiconductor die 100a may transmit data d1 to dn, output from the first logic circuit 120, to the second semiconductor die 200a via the plurality of interconnects 30, and the second interface circuit 210a of the second semiconductor die 200a may transmit data d1 to dn, received from the first semiconductor die 100a via the plurality of interconnects 30, to the second logic circuit 220.

For example, n pieces of data d1 to dn output from the first logic circuit 120 are transmitted to the second logic circuit 220, via the plurality of second flip-flops F21 to F2n of the second scan chain 13, the repair path (e.g., the first repair path) of the first repair logic 12, n first flip-flops among the plurality of first flip-flops F11 to F1m in the first scan chain 11, n transmitting circuits among the plurality of transmitting circuits D1 to Dm, n interconnects among the plurality of interconnects 30, n receiving circuits among the plurality of receiving circuits R1 to Rm, n third flip-flops among the plurality of third flip-flops F31 to F3m in the third scan chain 21, the repair path (e.g., the second repair path) of the second repair logic 22, and the plurality of fourth flip-flops F41 to F4n in the fourth scan chain 23. The n data d1 to dn may be transmitted simultaneously (or in parallel).

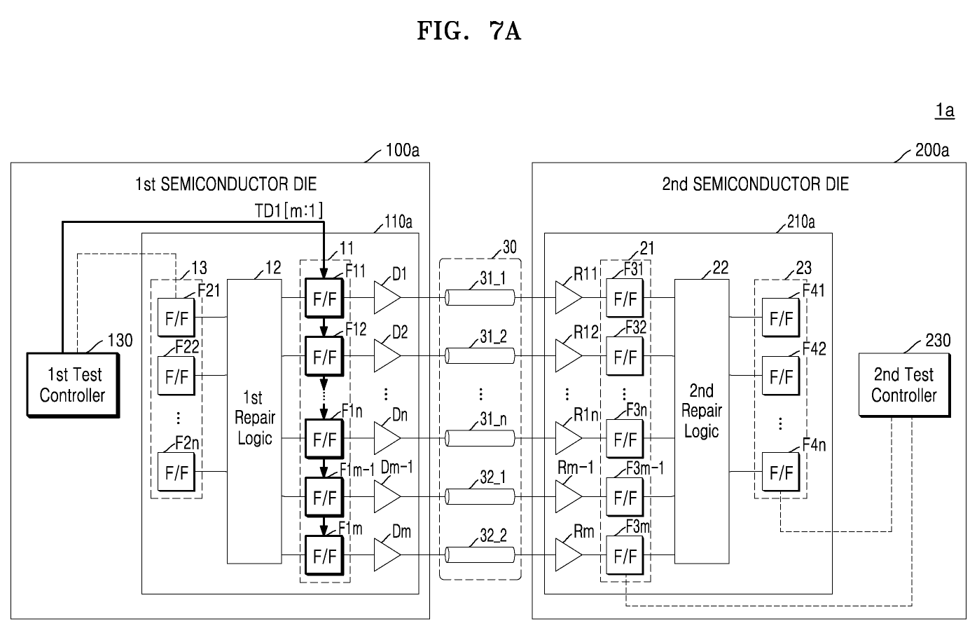

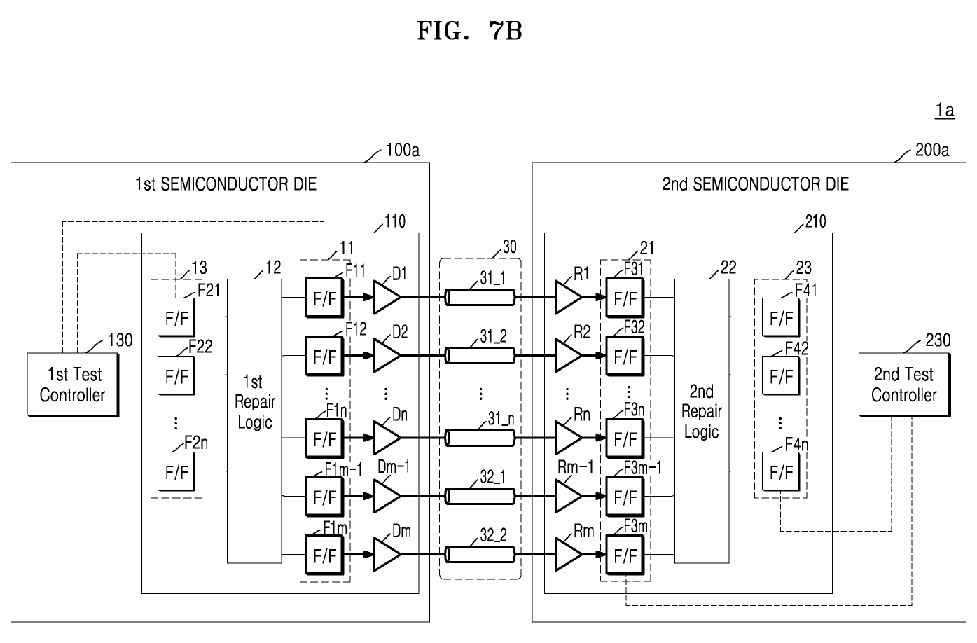

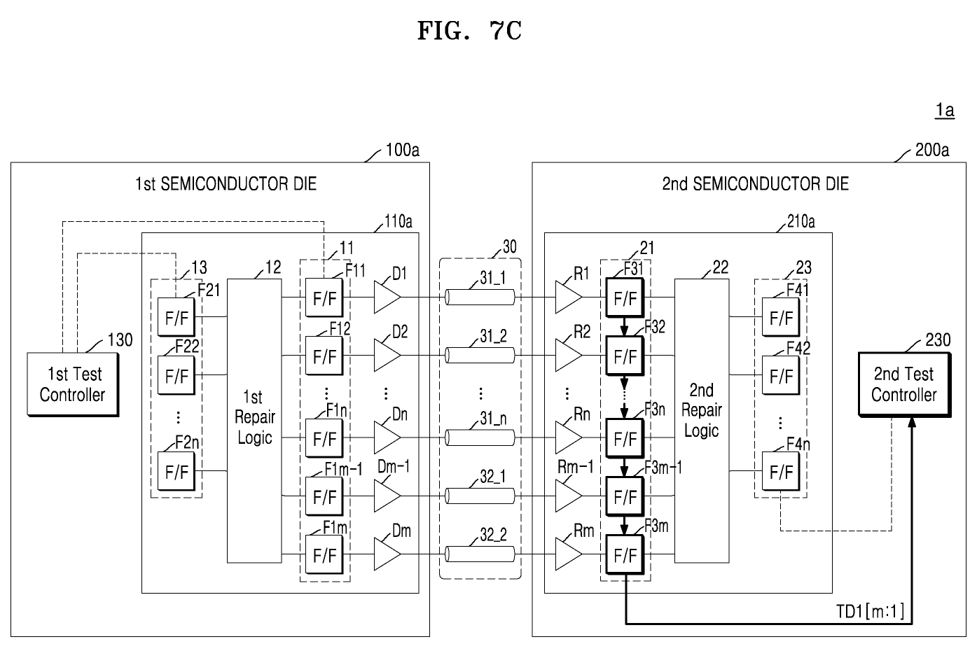

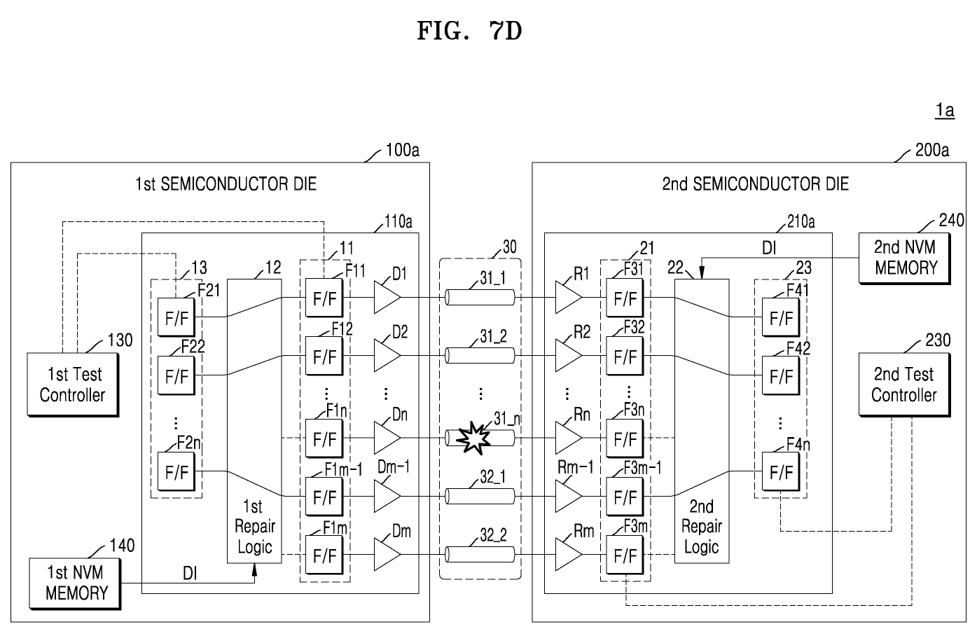

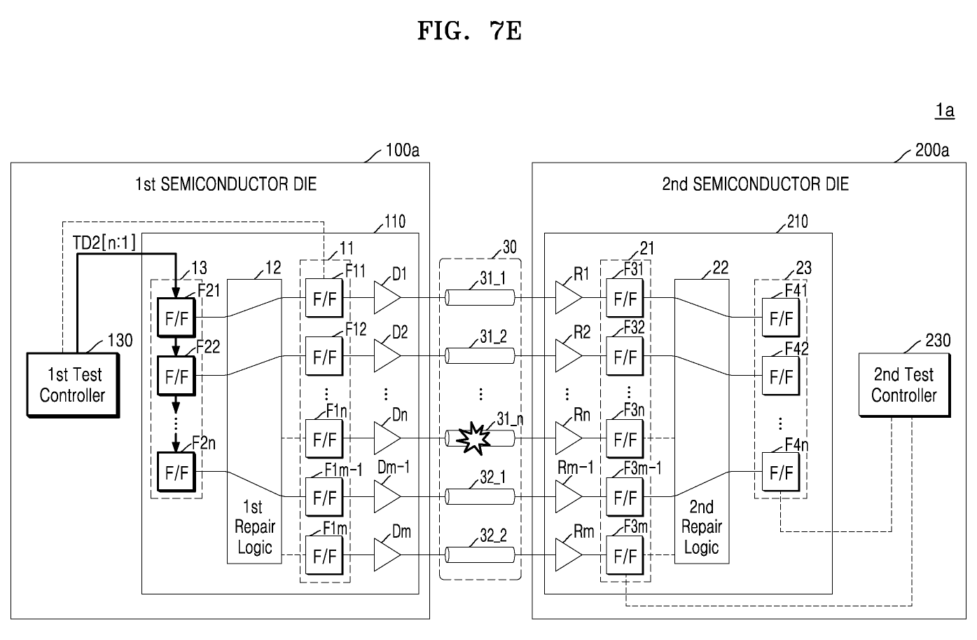

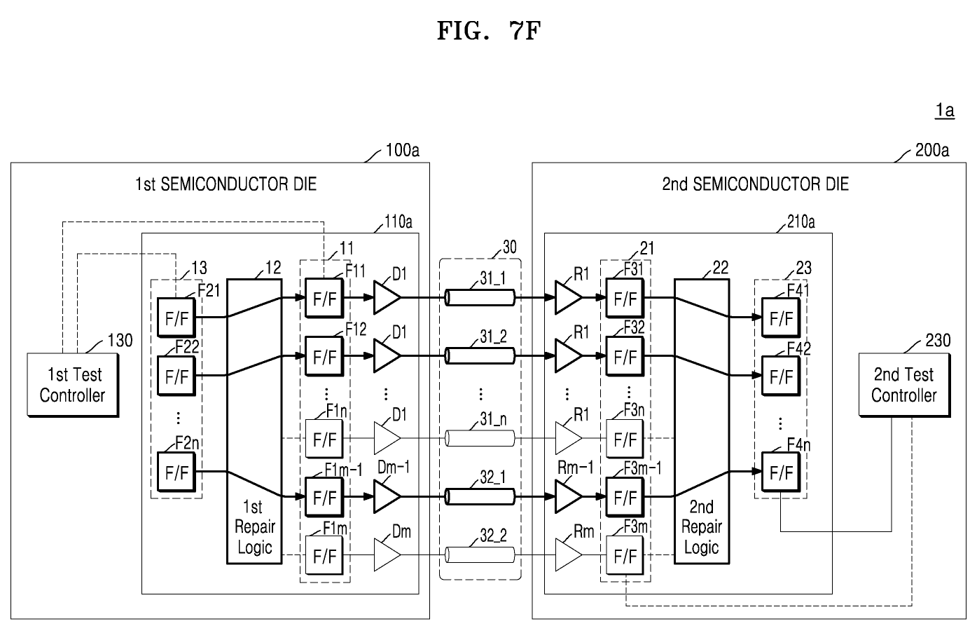

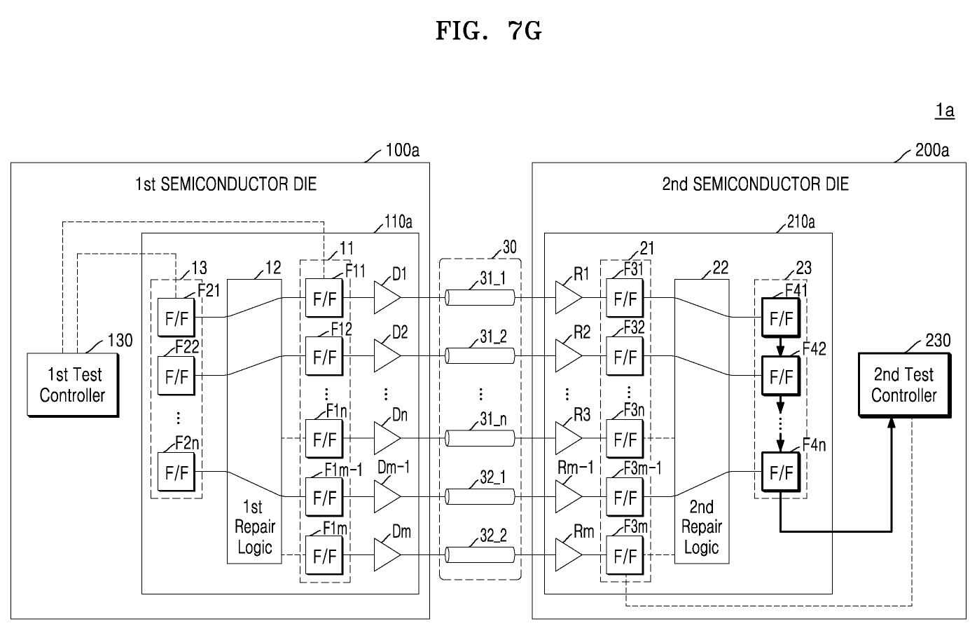

FIGS. 7A to 7G sequentially illustrate a test method of the semiconductor device 1a, according to one or more embodiments.

Specifically, FIGS. 7A to 7C illustrate operations of the first test performed during the first test period, FIG. 7D illustrates the execution of repair, and FIGS. 7E to 7G illustrate operations of the second test performed during the second test period.

Referring to FIG. 7A, the plurality of first flip-flops F11 to F1m in the first scan chain 11 of the first interface circuit 110a are connected in series to each other. The first test controller 130 may provide first test data TD1[m:1] to the first scan chain 11. The first test data TD1[m:1] may have m bits. The first test data TD1[m:1] is serially shifted into the plurality of first flip-flops F11 to F1m. The plurality of first flip-flops F11 to F1m may temporarily store the first test data TD1[m:1].

Referring to FIG. 7B, the plurality of first flip-flops F11 to F1m may output the first test data TD1[m:1]. The m bits of the first test data TD1[m:1] may be output simultaneously (in parallel) to the plurality of transmitting circuits D1 to Dm. The plurality of transmitting circuits D1 to Dm may transmit the first test data TD1[m:1] to the plurality of interconnects 30 (e.g., the first to nth normal interconnects 31_1 to 31_n and the redundant interconnects 32_1 and 32_2).

The plurality of receiving circuits R1 to Rm of the second interface circuit 210a may receive first received test data TD1R[m:1] based on first test data TD1[m:1] from the plurality of interconnects 30. The first received test data TD1R[m:1] may be the same as or different from the first test data TD1[m:1]. For example, when there is a defect in the plurality of interconnects 30, the first received test data TD1R[m:1] may be different from the first test data TD1[m:1].

The plurality of receiving circuits R1 to Rm may output the first received test data TD1R[m:1] to the plurality of third flip-flops F31 to F3m of the third scan chain 21. Accordingly, the first test data TD1[m:1] may be transmitted from the plurality of first flip-flops F11 to F1m of the first scan chain 11 to the plurality of third flip-flops F31 to F3m of the third scan chain 21. The plurality of third flip-flops F31 to F3m may temporarily store the first received test data TD1R[m:1].

Referring to FIG. 7C, the plurality of third flip-flops F31 to F3m of the third scan chain 21 may be connected in series, the plurality of third flip-flops F31 to F3m may serially shift out the stored first received test data TD1R[m:1], and the first received test data TD1R[m:1] may be transmitted to the second test controller 230.

As described with reference to FIG. 5A, the second test controller 230 may determine whether there is a defect in the plurality of interconnects 30 (e.g., the first test path) based on the first received test data TD1R[m:1], and may generate the defect information representing the defective interconnect (e.g., the defective path) among the plurality of interconnects 30 (e.g., the first to nth interconnects 31_1 to 31_n).

Referring to FIG. 7D, defect information DI may be stored in the first non-volatile memory 140 of the first semiconductor die 100a and the second non-volatile memory 240 of the second semiconductor die 200a. The first repair logic 12 may set the first repair path based on the defect information DI provided from the first non-volatile memory 140. The second repair logic 22 may set the second repair path based on the defect information DI provided from the second non-volatile memory 240.

In one or more embodiments, a first selection signal generated based on the defect information DI may be stored in the first non-volatile memory 140, and a second selection signal generated based on the defect information DI may be stored in the second non-volatile memory 240. The first repair logic 12 may set the first repair path based on the first selection signal, and the second repair logic 22 may set the second repair path based on the second selection signal.

The first repair logic 12 may connect, in one-to-one correspondence, the plurality of second flip-flops F21 to F2n of the second scan chain 13 to the n first flip-flops corresponding to the first repair path among the plurality of first flip-flops F11 to F1m of the first scan chain 11. The second repair logic 22 may connect, in one-to-one correspondence, the n third flip-flops corresponding to the second repair path among the plurality of third flip-flops F31 to F3m of the third scan chain 21 to the plurality of fourth flip-flops F41 to F4n of the fourth scan chain 23.

For example, when the nth normal interconnect 31_n among the plurality of interconnects 30 is defective, the first repair logic 12 and the second repair logic 22 may set the first and second repair paths, and a non-defective redundant interconnect (e.g., the redundant interconnect 32_1) among the redundant interconnects 32_1 and 32_2 may replace the nth normal interconnect 31_n. The first repair logic 12 may connect the second flip-flop F2n of the second scan chain 13 to the first flip-flop F1m-1 corresponding to the redundant interconnect 32_1 among the plurality of first flip-flops F11 to F1m of the first scan chain 11, but rather than to the first flip-flop F1n corresponding to the nth normal interconnect 31_n. The second repair logic 22 may connect the fourth flip-flop F4n of the fourth scan chain 23 to the third flip-flop F3m-1 corresponding to the redundant interconnect 32_1 among the plurality of third flip-flops F31 to F3m of the third scan chain 21, but rather than to the third flip-flop F3n corresponding to the nth normal interconnect 31_n.

Referring to FIG. 7E, the plurality of second flip-flops F21 to F2n in the second scan chain 13 of the first interface circuit 110a are connected in series. The first test controller 130 may provide second test data TD2[n:1] to the second scan chain 13. The second test data TD2[n:1] may have n bits. The second test data TD2[n:1] is serially shifted into the plurality of second flip-flops F21 to F2n. The plurality of second flip-flops F21 to F2n may temporarily store the second test data TD2[n:1].

Referring to FIG. 7F, the plurality of second flip-flops F21 to F2n may output the second test data TD2[n:1]. The n bits of the second test data TD2[n:1] may be output simultaneously (in parallel) to the first repair logic 12. The first repair logic 12 may output, via the first repair path, the second test data TD2[n:1] to the n first flip-flops F11, F12, ..., and F1m-1 corresponding to the first repair path among the plurality of first flip-flops F11 to F1m of the first scan chain 11.

The n first flip-flops F11, F12, ..., and F1m-1 may temporarily store the second test data TD2[n:1] and output the second test data TD2[n:1] to the corresponding n transmitting circuits D1, D2, ..., and Dm-1 among the plurality of transmitting circuits D1 to Dm. The n transmitting circuits D1, D2, ..., and Dm-1 may transmit the second test data TD2[n:1] to n non-defective interconnects 31_1, 31_2, ..., and 32_1 among the plurality of interconnects 30.

The n receiving circuits R1, R2, ..., and Rm-1 corresponding to the n non-defective interconnects 31_1, 31_2, ..., and 32_1 among the plurality of receiving circuits R1 to Rm of the second interface circuit 210a may receive second received test data TD2R[n:1] based on the second test data TD2[n:1] from the n non-defective interconnects 31_1, 31_2, ..., and 32_1. The n receiving circuits R1, R2, ..., and Rm-1 may output the second received test data TD2R[n:1] to the corresponding n third flip-flops F31, F32, ..., and F3m-1 among the plurality of third flip-flops F31 to F3m of the third scan chain 21. The n third flip-flops F31, F32, ..., and F3m-1 may temporarily store the second received test data TD2R[n:1] and output the second received test data TD2R[n:1] to the second repair logic 22. The second repair logic 22 may simultaneously (in parallel) output the second received test data TD2R[n:1], received via the second repair path, to the plurality of fourth flip-flops F41 to F4n of the fourth scan chain 23. Accordingly, the second test data TD2[n:1] may be transmitted from the plurality of second flip-flops F21 to F2n of the second scan chain 13 to the plurality of fourth flip-flops F41 to F4n of the fourth scan chain 23. The plurality of fourth flip-flops F41 to F4n may temporarily store the second received test data TD2R[n:1].

Referring to FIG. 7G, the plurality of fourth flip-flops F41 to F4n of the fourth scan chain 23 may be connected in series, the plurality of fourth flip-flops F41 to F4n of the fourth scan chain 23 may shift output the second received test data TD2R[n:1], and the second received test data TD2R[n:1] may be transmitted to the second test controller 230.

As described with reference to FIG. 5B, the second test controller 230 may determine, based on the second received test data TD2R[n:1], whether there is a defect in the data path (e.g., the second test path) from the second scan chain 13 to the fourth scan chain 23.

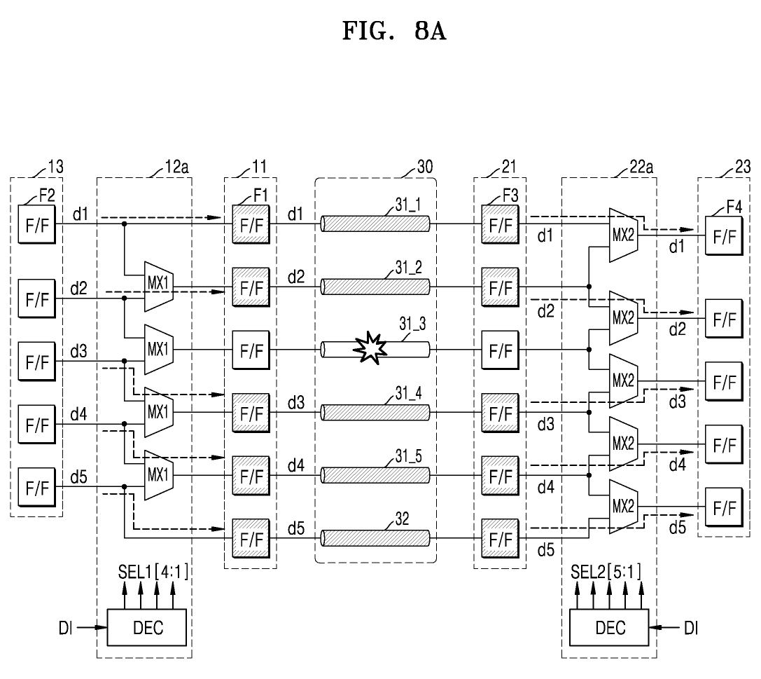

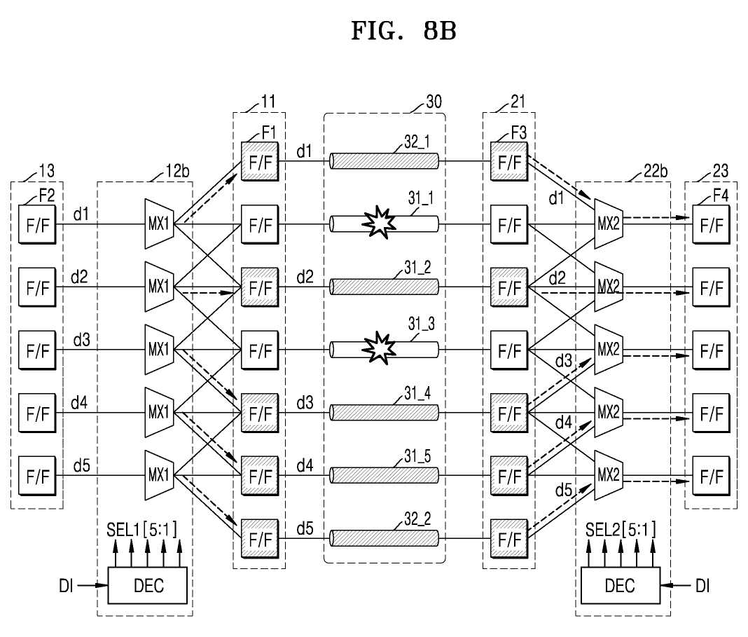

FIGS. 8A and 8B illustrate examples of first repair logics 12a and 12b and second repair logics 22a and 22b provided in the semiconductor device 1a according to one or more embodiments.

The plurality of transmitting circuits D1 to Dm (see FIG. 3) are connected between the first scan chain 11 and the plurality of interconnects 30, and the plurality of receiving circuits R1 to Rm (see FIG. 3) are connected between the third scan chain 21 and the plurality of interconnects 30, as shown in FIG. 3.

Referring to FIG. 8A, the first repair logic 12a and the second repair logic 22a may each be implemented by a plurality of multiplexers MX1 and MX2.

For convenience of description, it may be assumed that the plurality of interconnects 30 include first to fifth normal interconnects 31_1 to 31_5 and a redundant interconnect 32, the first scan chain 11 includes six first flip-flops F1, the second scan chain 13 includes five second flip-flops F2, the third scan chain 21 includes six third flip-flops F3, and the fourth scan chain 23 includes five fourth flip-flops F4.

The first repair logic 12a may include the plurality of multiplexers MX1 and a first decoder DEC1.

The first decoder DEC1 may decode the defect information DI and generate a first selection signal SEL1[4:1]. Bits of the first selection signal SEL1[4:1] may each be provided as a selection signal to a respective one of the plurality of multiplexers MX1.

Each of the plurality of multiplexers MX1 may receive two pieces of input data (or input signals) from two corresponding second flip-flops F2 of the second scan chain 13, and may output one of the two pieces of input data or not output the input data in response to the selection signal. Accordingly, the repair path (e.g., the first repair path) may be set.

For example, when it is determined that the third normal interconnect 31_3 is defective based on the first test result, the defect information DI may indicate that the third normal interconnect 31_3 is defective. In response to the first selection signal SEL1[4:1] generated based on the defect information DI, the plurality of multiplexers MX1 of the first repair logic 12a may set the first repair path, and thus, the first to fifth pieces of data d1 to d5 output from the plurality of second flip-flops F2 of the second scan chain 13 may be transmitted to the first, second, fourth, and fifth normal interconnects 31_1, 31_2, 31_4, and 31_5 and the redundant interconnect 32. Specifically, in response to the first selection signal SEL1[4:1], the plurality of multiplexers MX1 in the first repair logic 12a may connect (e.g., connect in one-to-one correspondence) the plurality of second flip-flops F2 of the second scan chain 13 to the five first flip-flops F1, corresponding to the first, second, fourth, and fifth normal interconnects 31_1, 31_2, 31_4, and 31_5 and the redundant interconnect 32, among the plurality of first flip-flops F1 of the first scan chain 11.

The second repair logic 22a may include the plurality of multiplexers MX2 and a second decoder DEC2.

The second decoder DEC2 may decode the defect information DI and generate a second selection signal SEL2[5:1]. Bits of the second selection signal SEL2[5:1] may each be provided as a selection signal to a respective one of the plurality of multiplexers MX2.

Each of the plurality of multiplexers MX2 may receive two pieces of input data (or input signals) from two corresponding interconnects among the plurality of interconnects 30, and may output one of the two pieces of input data in response to the selection signal. Accordingly, the repair path (e.g., the second repair path) may be set.

For example, in response to the second selection signal SEL2[5:1] generated based on the defect information DI, the plurality of multiplexers MX2 of the second repair logic 22a may set the second repair path, and thus, the first to fifth pieces of data d1 to d5 received from the first, second, fourth, and fifth normal interconnects 31_1, 31_2, 31_4, and 31_5 and the redundant interconnect 32 may be respectively output to the plurality of fourth flip-flops F4 of the fourth scan chain 23. Specifically, in response to the second selection signal SEL2[5:1], the plurality of multiplexers MX2 in the second repair logic 22a may connect (e.g., connect in one-to-one correspondence) the plurality of fourth flip-flops F4 of the fourth scan chain 23 to the five third flip-flops F3, corresponding to the first, second, fourth, and fifth normal interconnects 31_1, 31_2, 31_4, and 31_5 and the redundant interconnect 32, among the plurality of third flip-flops F3 of the third scan chain 21. Accordingly, the redundant interconnect 32 may indirectly replace the third normal interconnect 31_3.

Referring to FIG. 8B, the first repair logic 12b and the second repair logic 22b may each be implemented by the plurality of multiplexers MX1 and MX2.

For convenience of description, it may be assumed that the plurality of interconnects 30 include first to fifth normal interconnects 31_1 to 31_5 and redundant interconnects 32_1 and 32_2, the first scan chain 11 includes seven first flip-flops F1, the second scan chain 13 includes five second flip-flops F2, the third scan chain 21 includes seven third flip-flops F3, and the fourth scan chain 23 includes five fourth flip-flops F4. In one or more embodiments, the redundant interconnects 32_1 and 32_2 may be arranged respectively on both sides of the first to fifth normal interconnects 31_1 to 31_5.

The first repair logic 12b may include a plurality of multiplexers MX1 and the first decoder DEC1.

The first decoder DEC1 may decode the defect information DI and generate a first selection signal SEL1[5:1]. Bits of the first selection signal SEL1[5:1] may each be provided as a selection signal to a respective one of the plurality of multiplexers MX1.

Each of the plurality of multiplexers MX1 may receive input data (or an input signal) from a corresponding second flip-flop F2 among the plurality of second flip-flops F2 in the second scan chain 13, and based on the selection signal, may output the input data to one of the corresponding three first flip-flops F1. Accordingly, the repair path (e.g., the first repair path) may be set.

For example, when it is determined that the first normal interconnect 31_1 and the third normal interconnect 31_3 are defective based on the first test result, the defect information DI may indicate that the first normal interconnect 31_1 and the third normal interconnect 31_3 are defective.

In response to the first selection signal SEL1[5:1] generated based on the defect information DI, the plurality of multiplexers MX1 of the first repair logic 12b may set the first repair path, and thus, the first to fifth pieces of data d1 to d5 output from the plurality of second flip-flops F2 of the second scan chain 13 may be transmitted to the second, fourth, and fifth normal interconnects 31_2, 31_4, and 31_5 and the redundant interconnects 32_1 and 32_2. Specifically, in response to the first selection signal SEL1[5:1], the plurality of multiplexers MX1 in the first repair logic 12b may connect (e.g., connect in one-to-one correspondence) the plurality of second flip-flops F2 of the second scan chain 13 to the five first flip-flops F1, corresponding to the second, fourth, and fifth normal interconnects 31_2, 31_4, and 31_5 and the redundant interconnects 32_1 and 32_2, among the plurality of first flip-flops F1 of the first scan chain 11.

The second repair logic 22b may include a plurality of multiplexers MX2 and a second decoder DEC2.

The second decoder DEC2 may decode the defect information DI and generate the second selection signal SEL2[5:1]. Bits of the second selection signal SEL2[5:1] may each be provided as a selection signal to a respective one of the plurality of multiplexers MX2.

Each of the plurality of multiplexers MX2 may receive three pieces of input data (or input signals) from three corresponding third flip-flops F3 of the third scan chain 21, and may output one of the three pieces of input data in response to the selection signal. Accordingly, the repair path (e.g., the second repair path) may be set.

For example, in response to the second selection signal SEL2[5:1] generated based on the defect information DI, the plurality of multiplexers MX2 of the second repair logic 22b may set the second repair path, and thus, the first to fifth pieces of data d1 to d5 received from the second, fourth, and fifth normal interconnects 31_2, 31_4, and 31_5 and the redundant interconnects 32_1 and 32_2 may be respectively output to the plurality of fourth flip-flops F4 of the fourth scan chain 23. Specifically, in response to the second selection signal SEL2[5:1], the plurality of multiplexers MX2 in the second repair logic 22b may connect (e.g., connect in one-to-one correspondence) the plurality of fourth flip-flops F4 of the fourth scan chain 23 to the five third flip-flops F3, corresponding to the second, fourth, and fifth normal interconnects 31_2, 31_4, and 31_5 and the redundant interconnects 32_1 and 32_2, among the plurality of third flip-flops F3 of the third scan chain 21. Accordingly, the redundant interconnect 32_1 may directly replace the first normal interconnect 31_1, and the redundant interconnect 32_2 may indirectly replace the third normal interconnect 31_3.

Above, examples of the first repair logics 12a and 12b and the second repair logics 22a and 22b provided in the semiconductor device 1a according to one or more embodiments have been described with reference to FIGS. 8A and 8B. However, the embodiment is not limited thereto, and the first repair logics 12a and 12b and the second repair logics 22a and 22b may be implemented in various other manners.

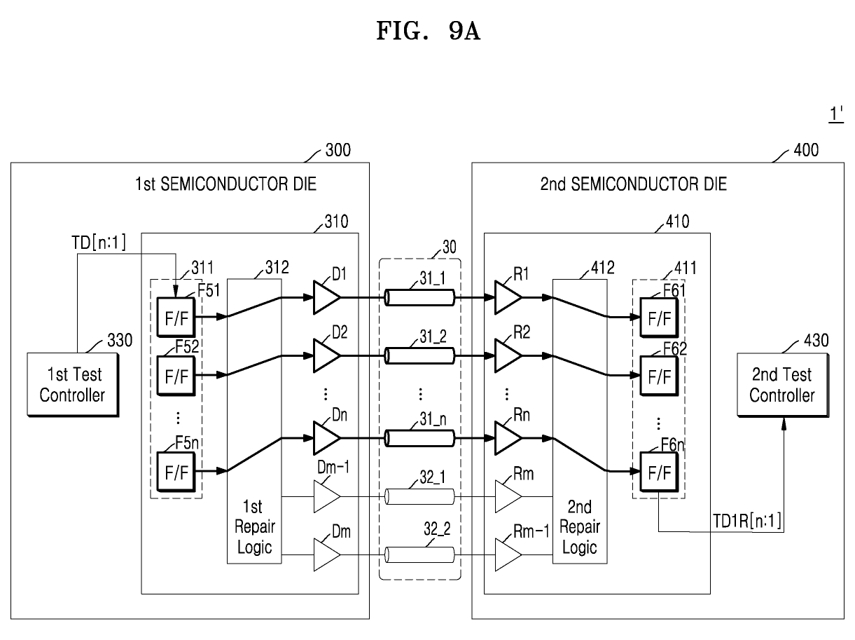

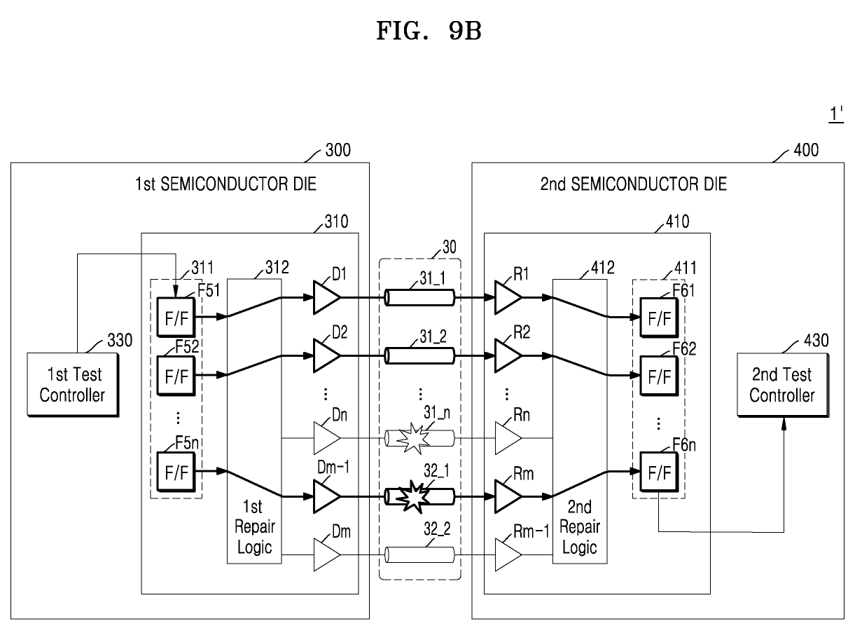

FIGS. 9A and 9B illustrate a test method for a semiconductor device 1’ according to a comparative example.

Referring to FIGS. 9A and 9B, the semiconductor device 1’ according to the comparative example may include a first semiconductor die 300, a second semiconductor die 400, and the plurality of interconnects 30, and the plurality of interconnects 30 may transmit signals between the first semiconductor die 300 and the second semiconductor die 400.

The first semiconductor die 300 may include a first interface circuit 310 and a first test controller 330, and the second semiconductor die 400 may include a second interface circuit 410 and a second test controller 430. The first semiconductor die 300 and the second semiconductor die 400 may further include a first logic circuit and a second logic circuit, respectively.

The first interface circuit 310 may include a first scan chain 311, a first repair logic 312, and a plurality of transmitting circuits D1 to Dm, and the second interface circuit 410 may include a second scan chain 411, a second repair logic 412, and a plurality of receiving circuits R1 to Rm.

The first scan chain 311 may include a plurality of first flip-flops F51 to F5n, and the first repair logic 312 may connect the plurality of first flip-flops F51 to F5n of the first scan chain 311 to the plurality of transmitting circuits D1 to Dm.

The second scan chain 411 may include a plurality of second flip-flops F61 to F6n, and the second repair logic 412 may connect the plurality of receiving circuits R1 to Rm to the plurality of second flip-flops F61 to F6n of the second scan chain 411.

Referring to FIG. 9A, the first repair logic 312 may basically connect the plurality of first flip-flops F51 to F5n of the first scan chain 311 to the first to nth transmitting circuits D1 to Dn in one-to-one correspondence. The second repair logic 412 may basically connect the first to nth receiving circuits R1 to Rn to the plurality of second flip-flops F61 to F6n of the second scan chain 411 in one-to-one correspondence.

The first test controller 330 may provide test data TD[n:1] to the first scan chain 311. The test data TD[n:1] may be transmitted to the second scan chain 411, via the first repair logic 312, the first to nth transmitting circuits D1 to Dn, the first to nth normal interconnects 31_1 to 31_n, the first to nth receiving circuits R1 to Rn, and the second repair logic 412. The second scan chain 411 may transmit received test data TDR[n:1] to the second test controller 430.

Based on the test results, a defective interconnect among the first to nth normal interconnects 31_1 to 31_n may be detected, and the defect information may be stored in non-volatile memory provided in each of the first interface circuit 310 and the second interface circuit 410.

The first repair logic 312 and the second repair logic 412 may set the repair paths (e.g., the first repair path and the second repair path) based on the defect information, and thus, the redundant interconnects 32_1 and 32_2 may replace defective normal interconnects.

Referring to FIG. 9B, the first repair logic 312 and the second repair logic 412 may set the repair path, and the redundant interconnect 32_1 may replace the defective nth normal interconnect 31_n. However, the redundant interconnect 32_1 may also be defective. In the test described with reference to FIG. 9A, since the test data TD[n:1] is transmitted via the first to nth normal interconnects 31_1 to 31_n, a defect in the redundant interconnects 32_1 and 32_2 may not be detected. Therefore, even though the first repair logic 312 and the second repair logic 412 have set the repair path, data may not be transmitted normally due to a defect in the redundant interconnect 32_1 that replaces the defective nth normal interconnect 31_n.

Therefore, after setting the repair path and performing a test again, when it is determined that the redundant interconnect 32_1 is defective, defect information may be generated again and stored in the non-volatile memory provided in each of the first interface circuit 310 and the second interface circuit 410.

As described above, in the semiconductor device 1’ according to the comparative example, when a defect exists in the repair path, the defect information indicating that the defect is in the repair path is stored again, the repair path is reset, and the test is performed again. Accordingly, tests may be performed repeatedly. In the worst case in which all k redundant interconnects (k being an integer greater than or equal to 2) are defective, k+1 tests may be performed, including the initial test, which may significantly increase the test time. Furthermore, it is difficult to clearly distinguish whether the defects detected by the test are caused by defects in the interconnects or by defects in the first and second repair logics 312 and 412.

However, as described above, in the semiconductor devices 1 and 1a according to embodiments, prior to setting the repair path, the first test is performed on the first test path that includes the plurality of interconnects 30 but excludes the first and second repair logics 12 and 22. Accordingly it may be accurately detected whether a defect occurs in the plurality of interconnects 30, and it may also be detected whether a defect occurs in the redundant interconnects.

After the repair path is set based on the defect information, the second test is performed on the entire signal path that includes not only the plurality of interconnects 30 but also the first and second repair logics 12 and 22. Accordingly, the presence or absence of defects in the entire signal path may be detected, and the operational reliability of the repair path may be verified.

Furthermore, in the semiconductor devices 1 and 1a according to embodiments, since a total of two tests, i.e., the first test (the pre-repair test) before setting the repair path and the second test (the post-repair test), are performed, the test time may be reduced.

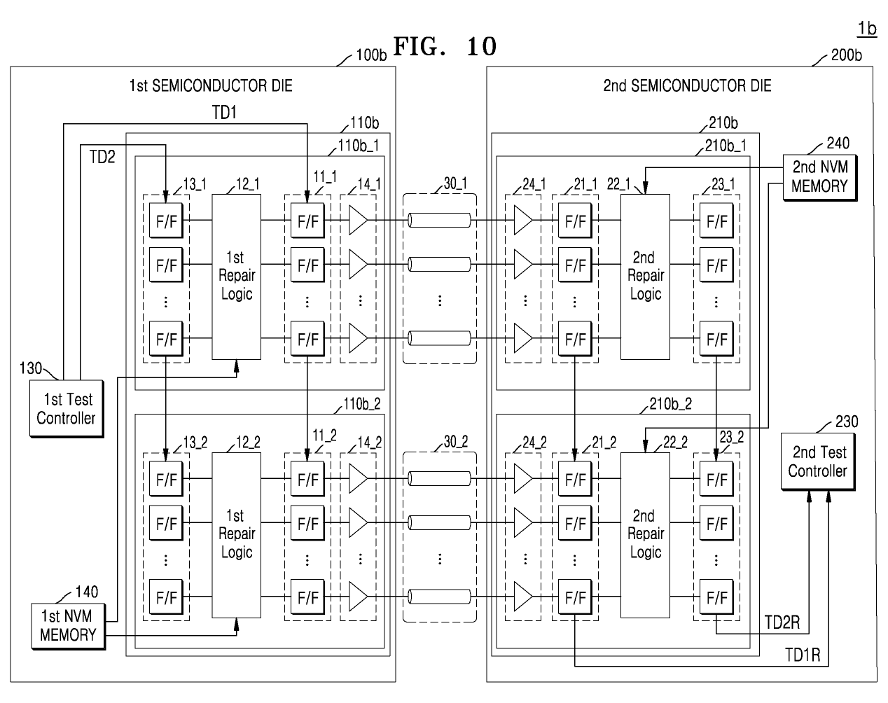

FIG. 10 is a block diagram showing a semiconductor device 1b according to one or more embodiments.

Referring to FIG. 10, the semiconductor device 1b may include a first semiconductor die 100b, a second semiconductor die 200b, a plurality of first interconnects 30_1, and a plurality of second interconnects 30_2. In one or more embodiments, the semiconductor device 1b is a 3D integrated circuit, and the first semiconductor die 100b and the second semiconductor die 200b may be stacked on each other in the vertical direction. The plurality of first interconnects 30_1 and the plurality of second interconnects 30_2 may each include normal interconnects and redundant interconnects.

The first semiconductor die 100b may include a first interface circuit 110b, the first test controller 130, and the first non-volatile memory 140, and the second semiconductor die 200b may include a second interface circuit 210b, the second test controller 230, and the second non-volatile memory 240. The first semiconductor die 100b may further include a first logic circuit connected to the first interface circuit 110b, and the second semiconductor die 200b may further include a second logic circuit connected to the second interface circuit 210b.

The first interface circuit 110b may include a first unit circuit 110b_1 and a second unit circuit 110b_2. The first unit circuit 110b_1 and the second unit circuit 110b_2 may have the same structure and include first scan chains 11_1 and 11_2, first repair logics 12_1 and 12_2, second scan chains 13_1 and 13_2, and a plurality of transmitting circuits 14_1 and 14_2, respectively. The plurality of transmitting circuits 14_1 of the first unit circuit 110b_1 may be connected to the plurality of first interconnects 30_1, and the plurality of transmitting circuits 14_2 of the second unit circuit 110b_2 may be connected to the plurality of second interconnects 30_2.

The second interface circuit 210b may include a third unit circuit 210b_1 and a fourth unit circuit 210b_2. The third unit circuit 210b_1 and the fourth unit circuit 210b_2 may have the same structure and include third scan chains 21_1 and 21_2, second repair logics 22_1 and 22_2, fourth scan chains 23_1 and 23_2, and plurality of receiving circuits 24_1 and 24_2. The plurality of receiving circuits 24_1 of the third unit circuit 210b_1 may be connected to the plurality of first interconnects 30_1, and the plurality of receiving circuits 24_2 of the fourth unit circuit 210b_2 may be connected to the plurality of second interconnects 30_2.

Herein, FIG. 10 illustrates that the first interface circuit 110b and the second interface circuit 210b each include two unit circuits, but this is for convenience of description. The first interface circuit 110b and the second interface circuit 210b may each include three or more unit circuits.

During the first test period, a plurality of flip-flops F/F in the first scan chains 11_1 and 11_2 of the first unit circuit 110b_1 and the second unit circuit 110b_2 may be connected in series, and the first test data TD1 received from the first test controller 130 may be serially shifted into the plurality of flip-flops F/F in the first scan chains 11_1 and 11_2.

The first scan chain 11_2 of the second unit circuit 110b_2 may receive lower half of the bits of the first test data TD1 shifted thereinto from the first scan chain 11_1 of the first unit circuit 110b_1. The lower half of the bits in the first test data TD1 may be temporarily stored in the first scan chain 11_2 of the second unit circuit 110b_2, and the upper half of the bits in the first test data TD1 may be temporarily stored in the first scan chain 11_1 of the first unit circuit 110b_1.

The first test data TD1 may be transmitted as the first received test data TD1R to the plurality of flip-flops F/F in the third scan chains 21_1 and 21_2, via the transmitting circuits 14_1 and 14_2, the plurality of first and second interconnects 30_1 and 30_2, and the receiving circuits 24_1 and 24_2.

The lower half of the bits in the first received test data TD1R may be temporarily stored in the third scan chain 21_2 of the fourth unit circuit 210b_2, and the upper half of the bits therein may be temporarily stored in the third scan chain 21_1 of the third unit circuit 210b_1.

The plurality of flip-flops F/F in the third scan chains 21_1 and 21_2 of the third unit circuit 210b_1 and the fourth unit circuit 210b_2 may be connected in series, and the first received test data TD1R may be serially shifted out of the plurality of flip-flops F/F in the third scan chains 21_1 and 21_2 and transmitted to the second test controller 230.

The defect information based on the test results of the first test is stored in the first and second non-volatile memories 140 and 240. Also, the first repair logics 12_1 and 12_2 of the first unit circuit 110b_1 and the second unit circuit 110b_2 may set a first repair path based on the defect information from the first non-volatile memory 140, and the second repair logics 22_1 and 22_2 of the third unit circuit 210b_1 and the fourth unit circuit 210b_2 may set a second repair path based on the defect information from the second non-volatile memory 240.

Subsequently, during the second test period, a plurality of flip-flops F/F in the second scan chains 13_1 and 13_2 of the first unit circuit 110b_1 and the second unit circuit 110b_2 may be connected in series, and the second test data TD2 received from the first test controller 130 may be serially shifted into the plurality of flip-flops F/F in the second scan chains 13_1 and 13_2.

The second test data TD2 may be transmitted as second received test data TD2R to the plurality of flip-flops F/F in the fourth scan chains 23_1 and 23_2, via the first repair logics 12_1 and 12_2, the first scan chains 11_1 and 12_1, the transmitting circuits 14_1 and 14_2, the plurality of first and second interconnects 30_1 and 30_2, the receiving circuits 24_1 and 24_2, the third scan chains 21_1 and 22_1, and the second repair logics 22_1 and 22_2.

The plurality of flip-flops F/F of the fourth scan chains 23_1 and 23_2 are connected in series, and the second received test data TD2R may be serially shifted out of the plurality of flip-flops F/F of the fourth scan chains 23_1 and 23_2 and transmitted to the second test controller 230.

As described above, the first interface circuit 110b and the second interface circuit 210b may be implemented as a plurality of unit circuits having the same structure, and these unit circuits are repeatedly arranged. Accordingly, test data may be easily generated, and test efficiency and the automation of interface circuit design may be improved.

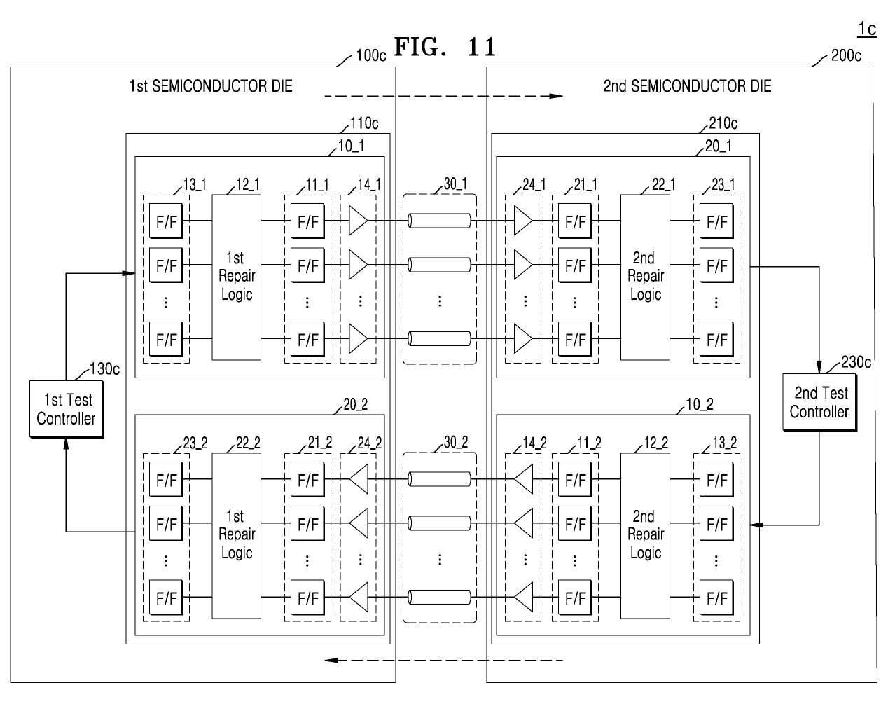

FIG. 11 is a block diagram showing a semiconductor device 1c according to one or more embodiments.

Referring to FIG. 11, the semiconductor device 1c may include a first semiconductor die 100c, a second semiconductor die 200c, the plurality of first interconnects 30_1, and the plurality of second interconnects 30_2. In one or more embodiments, the semiconductor device 1c is a 3D integrated circuit, and the first semiconductor die 100c and the second semiconductor die 200c may be stacked on each other in the vertical direction. The plurality of first interconnects 30_1 and the plurality of second interconnects 30_2 may each include normal interconnects and redundant interconnects.

The first semiconductor die 100c may include a first interface circuit 110c and a first test controller 130c, and the second semiconductor die 200c may include a second interface circuit 210c and a second test controller 230c. The first semiconductor die 100c may further include a first logic circuit connected to the first interface circuit 110c and a first non-volatile memory for storing defect information, and the second semiconductor die 200c may further include a second logic circuit connected to the second interface circuit 210c and a second non-volatile memory for storing defect information.

The first interface circuit 110c may include a transmit interface circuit 10_1 and a receive interface circuit 20_2, and the second interface circuit 210c may include a receive interface circuit 20_1 and a transmit interface circuit 10_2.

The transmit interface circuit 10_1 of the first interface circuit 110c and the receive interface circuit 20_1 of the second interface circuit 210c (hereinafter referred to as the “first transmit/receive interface circuit pair 10_1 and 20_1”) may be responsible for transmitting signals (data) from the first semiconductor die 100c to the second semiconductor die 200c. The transmit interface circuit 10_2 of the second interface circuit 210c and the receive interface circuit 20_2 of the first interface circuit 110c (hereinafter referred to as the “second transmit/receive interface circuit pair 10_2 and 20_2”) may be responsible for transmitting signals from the second semiconductor die 200c to the first semiconductor die 100c. Accordingly, the first semiconductor die 100c and the second semiconductor die 200c may exchange data with each other.

The transmit interface circuits 10_1 and 10_2 may include the first scan chains 11_1 and 11_2, the first repair logics 12_1 and 12_2, the second scan chains 13_1 and 13_2, and the plurality of transmitting circuits 14_1 and 14_2. The receive interface circuits 20_1 and 20_2 may include the third scan chains 21_1 and 21_2, the second repair logics 22_1 and 22_2, the fourth scan chains 23_1 and 23_2, and the plurality of receiving circuits 24_1 and 24_2.

In the embodiment, the transmit interface circuits 10_1 and 10_2 and the receive interface circuits 20_1 and 20_2 may each include a plurality of unit circuits having the same structure, as described with reference to FIG. 10.

The transmit interface circuits 10_1 and 10_2 may operate in an identical or similar manner to the first interface circuit 110a of FIG. 3, and the receive interface circuits 20_1 and 20_2 may operate in an identical or similar manner to the second interface circuit 210a of FIG. 3.

The first test controller 130c and the second test controller 230c may control the first interface circuit 110c and the second interface circuit 210c to perform tests in the test mode. The first test controller 130c and the second test controller 230c may provide test data to the transmit interface circuits 10_1 and 10_2, respectively, and receive the test data from the receive interface circuits 20_1 and 20_2 to determine (analyze) the test results. The operations of the first test controller 130c and the second test controller 230c are the same as or similar to those described with reference to FIGS. 3, 5A, 5B, 7A and 7G,

FIG. 11 illustrates that the first transmit/receive interface pair 10_1 and 20_1 are connected to the plurality of first interconnects 30_1, and the second transmit/receive interface pair 10_2 and 20_2 are connected to the plurality of second interconnects 30_2. Accordingly, the first transmit/receive interface pair 10_1 and 20_1 and the second transmit/receive interface pair 10_2 and 20_2 may be connected to different interconnects. However, the embodiment is not limited thereto, and the first transmit/receive interface pair 10_1 and 20_1 and the second transmit/receive interface pair 10_2 and 20_2 may also share a plurality of interconnects.

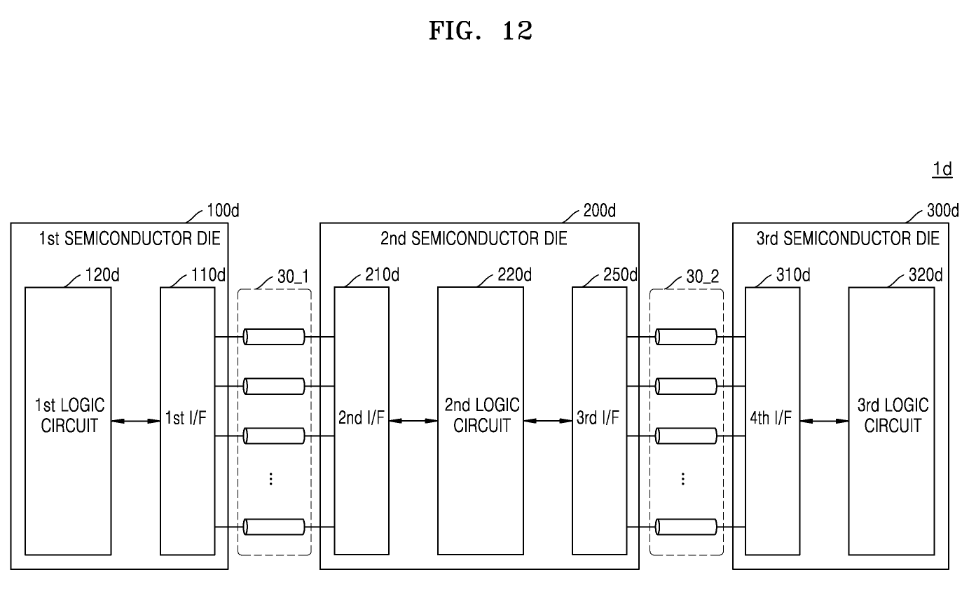

FIG. 12 is a block diagram showing a semiconductor device 1d according to one or more embodiments.

Referring to FIG. 12, the semiconductor device 1d may include a first semiconductor die 100d, a second semiconductor die 200d, a third semiconductor die 300d, the plurality of first interconnects 30_1, and the plurality of second interconnects 30_2. The plurality of first interconnects 30_1 may be connected between the first semiconductor die 100d and the second semiconductor die 200d, and the plurality of second interconnects 30_2 may be connected between the second semiconductor die 200d and the third semiconductor die 300d. The plurality of first interconnects 30_1 and the plurality of second interconnects 30_2 may each include normal interconnects and redundant interconnects.

In one or more embodiments, the first semiconductor die 100d, the second semiconductor die 200d, and the third semiconductor die 300d may be stacked on one another in the vertical direction. In one or more embodiments, the first semiconductor die 100d and the second semiconductor die 200d may be stacked in the vertical direction, the second semiconductor die 200d and the third semiconductor die 300d may be stacked in the vertical direction, and the first semiconductor die 100d and the third semiconductor die 300d may be at the same level in the vertical direction. The semiconductor device 1d may be referred to as a 3D integrated circuit.

The first semiconductor die 100d may include a first interface circuit 110d and a first logic circuit 120d, the second semiconductor die 200d may include a second interface circuit 210d, a second logic circuit 220d, and a third interface circuit 250d, and the third semiconductor die 300d may include a fourth interface circuit 310d and a third logic circuit 320d. The first semiconductor die 100d, the second semiconductor die 200d, and the third semiconductor die 300d may each further include a test controller and non-volatile memory for storing defect information.

The first interface circuit 110d and the second interface circuit 210d may be responsible for transmitting and receiving signals (data) between the first semiconductor die 100d and the second semiconductor die 200d, and the third interface circuit 250d and the fourth interface circuit 310d may be responsible for transmitting and receiving signals (data) between the second semiconductor die 200d and the third semiconductor die 300d.

The first interface circuits 110, 110a, 110b, and 110c and the second interface circuits 210, 210a, 210b, and 210c described with reference to FIGS. 1, 3, 10 and 11, may be applied to the first interface circuit 110d and the second interface circuit 210d, and may also be applied to the third interface circuit 250d and the fourth interface circuit 310d.

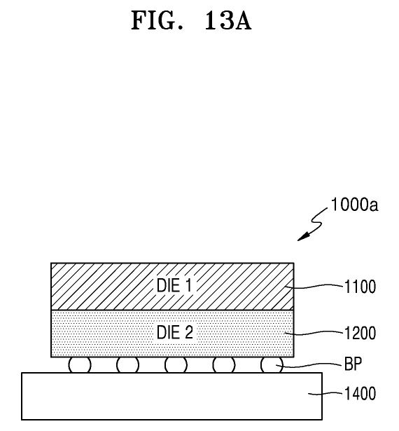

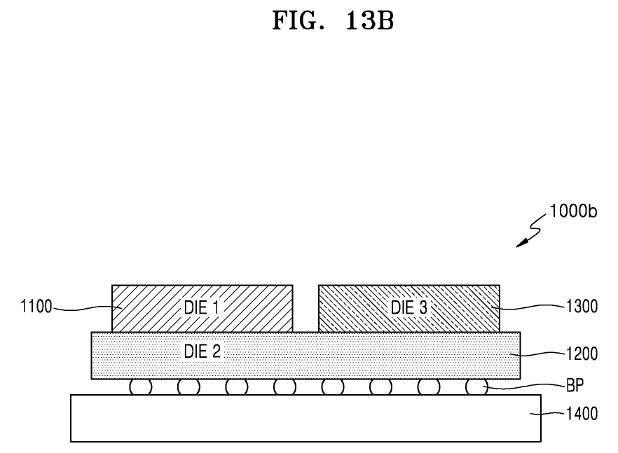

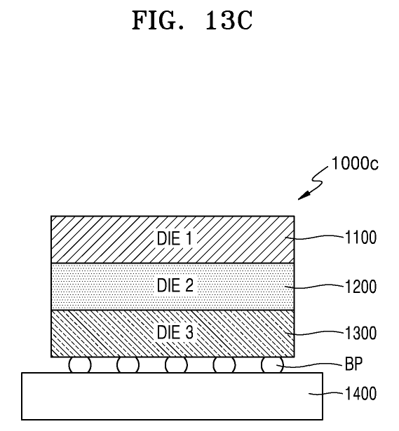

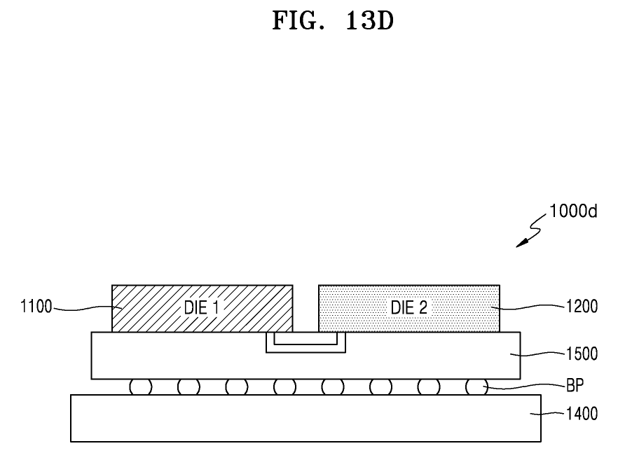

FIGS. 13A, 13B, 13C and 13D, are structural diagrams illustrating semiconductor devices 1000a, 1000b, 1000c, and 1000d according to embodiments.

Referring to FIG. 13A, the semiconductor device 1000a may include a first semiconductor die (DIE 1) 1100 and a second semiconductor die (DIE 2) 1200, and the DIE1 1100 and the DIE2 1200 may be stacked on each other in the vertical direction.

As described above, the DIE 1 1100 and the DIE 2 1200 may be electrically connected to each other via a plurality of interconnects implemented as TSVs, micro bumps, hybrid bonding, or the like. The DIE 2 1200 may be connected to a package substrate 1400 (or an interposer) via bumps BP. The bumps BP may each be implemented as, for example, a solder bump, a flip-chip bump, or a micro bump.

Referring to FIGS. 13B and 13C, the semiconductor devices 1000b and 1000c may each include the DIE 1 1100, the DIE 2 1200, and a DIE 3 1300. In one or more embodiments, the first semiconductor die 100d, the second semiconductor die 200d, and the third semiconductor die 300d described with reference to FIG. 12 may each be implemented as the DIE 1 1100, the DIE 2 1200, and the DIE 3 1300.

Referring to FIG. 13B, the DIE 1 1100 and the DIE 3 1300 may be stacked on the DIE 2 1200. Referring to FIG. 13C, the DIE 1 1100, the DIE 2 1200, and the DIE 3 1300 may be stacked on one another in the vertical direction.

The DIE 1 1100 and the DIE 2 1200 may be electrically connected to each other via a plurality of interconnects, and the DIE 2 1200 and the DIE 3 1300 may be electrically connected to each other via a plurality of interconnects. The DIE 2 1200 may be connected to the package substrate 1400 (or the interposer) via the bumps BP.

Referring to FIG. 13D, the DIE 1 110 and the DIE 2 1200 may be stacked on an interposer 1500 and electrically connected to each other via the interposer 1500.

The DIE 1 1100 and the DIE 2 1200 may be connected to the interposer 1500 via bumps (e.g., micro bumps, flip-chip bumps, etc.) or hybrid bonding. The DIE 1 1100 and the DIE 2 1200 may be electrically connected to each other by TSVs, metal wires, vias, or active elements (e.g., buffers, switches, multiplexers, etc.) inside the interposer 1500. At least one of the TSVs, the metal wires, the vias, and the active elements inside the interposer 1500 may constitute the interconnects in conjunction with hybrid bonds or bumps that connect the DIE 1 1100 and the DIE 2 1200 to the interposer 1500.

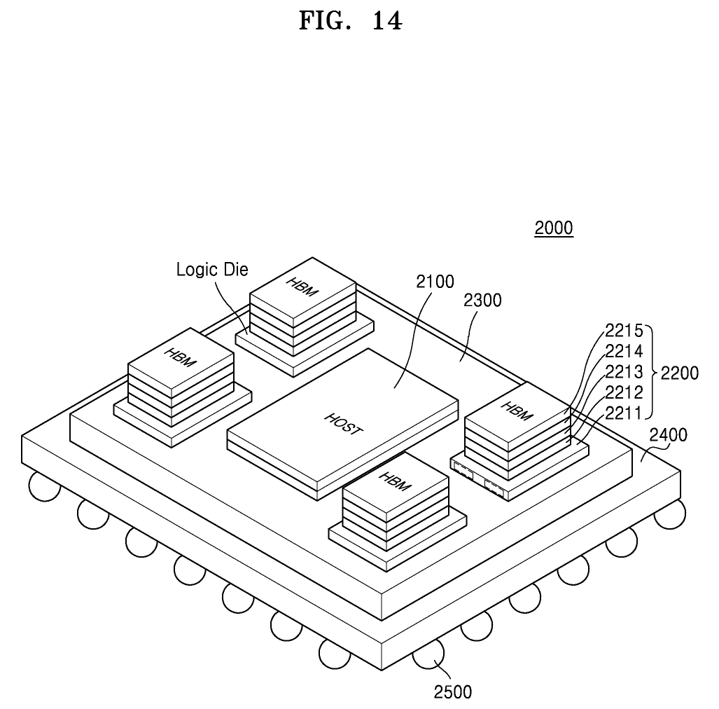

FIG. 14 is a structural diagram illustrating an example of an electronic system 2000 according to one or more embodiments.

Referring to FIG. 14, the electronic system 2000 may include a host 2100, a plurality of high bandwidth memories (HBMs) 2200, an interposer 2300, and a package substrate 2400.

The host 2100 may correspond to various other semiconductor devices that request memory access. The host 2100 may be implemented as the 3D integrated circuit according to the embodiments described above. The host 2100 may include two or more vertically stacked semiconductor dies, and the semiconductor dies may be electrically connected to each other via a plurality of interconnects. The interface circuit in each of the semiconductor dies may include two independent scan chains for verifying the interface between the semiconductor dies, and a first test (a pre-repair test) and a second test (a post-repair test) may be performed on two test circuits based on the two scan chains. Accordingly, defects in the plurality of interconnects themselves and defects in the entire signal path (the data path) including the interface circuits may be detected.

A CPU, a GPU, an NPU/AI accelerator, a DSP, a PMIC, a memory controller, an I/O interface circuit, a security circuit, and on-chip memory may be implemented in the semiconductor dies of the host 2100. For example, circuits with high operating speeds, such as the CPU, the GPU, and the NPU/AI accelerator, may be integrated on an upper semiconductor die (e.g., a semiconductor die located relatively far from the interposer 2300), and other circuits may be integrated on a lower semiconductor die (e.g., a semiconductor die located relatively close to the interposer 2300).

The HBM 2200 may include a plurality of semiconductor dies 2211 to 2215, and the plurality of semiconductor dies 2211 to 2215 may be electrically connected to each other via a plurality of interconnects.

The host 2100 and the HBM 2200 may be mounted on the interposer 2300, and the interposer 2300 may be mounted on the package substrate 2400. The interposer 2300 may be implemented in various other forms, such as a silicon (TSV)-type interposer, a printed circuit board (PCB)-based organic-type interposer, or an embedded multi-die interconnect bridge (EMIB)-type interposer that is a non-TSV. A conductive means, such as a solder ball 2500, may be mounted on a lower portion of the package substrate 2400.

One or more embodiments of the present disclosure may provide a3D integrated circuit including a first semiconductor die including a first interface circuit and a first test controller, a second semiconductor die including a second interface circuit and a second test controller, and a plurality of interconnects connected between the first semiconductor die and the second semiconductor die and configured to transmit a signal, wherein the first interface circuit includes a first unit circuit. The first unit circuit includes a first scan chain configured to, during a first test period, receive first test data for performing a first test from the first test controller and output the first test data, a first repair logic configured to, based on defect information generated from test results of the first test, set a first repair path for replacing a defective interconnect among the plurality of interconnects with a non-defective redundant interconnect, and a second scan chain configured to, during a second test period after the first repair path is set, receive second test data for performing a second test from the first test controller and output the second test data.

In one or more embodiments, the first interface circuit may further include a second unit circuit, wherein the second unit circuit includes a third scan chain configured to, during the first test period, receive the first test data from the first scan chain and output the first test data, a second repair logic configured to set a second repair path based on the defect information, and a fourth scan chain configured to, during a second test period after the second repair path is set, receive the second test data from the second scan chain and output the second test data.

In one or more embodiments, a non-defective redundant interconnect among the plurality of interconnects may replace a defective interconnect along the first repair path of the first repair logic and the second repair path of the second repair logic.

In one or more embodiments, the first scan chain may include m first scan cells (where m is an integer greater than or equal to 3), and the third scan chain may include m third scan cells. During the first test period, the m first scan cells of the first scan chain and the m third scan cells of the third scan chain may be connected in series, and the first test data may be shifted into the m first scan cells and the m third scan cells.

In one or more embodiments, during the first test period, a plurality of bits of the first test data stored in the first scan chain and the third scan chain may be transmitted in parallel to the plurality of interconnects.

In one or more embodiments, the second scan chain may include n second scan cells (where n is an integer greater than or equal to 2), and the fourth scan chain may include n fourth scan cells. During the second test period, the n second scan cells of the second scan chain and the n fourth scan cells of the fourth scan chain may be connected in series, and the second test data may be serially shifted into the n second scan cells and the n fourth scan cells.

In one or more embodiments, during the second test period, a plurality of bits of the second test data stored in the second scan chain and the fourth scan chain may be output in parallel via the first repair path of the first repair logic and the second repair path of the second repair logic.

In one or more embodiments, the second interface circuit may include a third unit circuit and a fourth unit circuit. The third unit circuit may include a fifth scan chain configured to, during the first test period, shift out the first test data received from the first semiconductor die to the second test controller, a third repair logic configured to set a third repair path based on the defect information, and a sixth scan chain configured to, during the second test period after the third repair path is set, shift out the second test data received from the first semiconductor die to the second test controller. The fourth unit circuit may include a seventh scan chain configured to, during the first test period, shift out the first test data received from the first semiconductor die to the fifth scan chain, a fourth repair logic configured to set a fourth repair path based on the defect information, and an eighth scan chain configured to, during the second test period after the fourth repair path is set, shift out the second test data received from the first semiconductor die to the sixth scan chain.

One or more embodiments may provide a semiconductor device, wherein the plurality of interconnects include n interconnects (where n is an integer greater than or equal to 2) and m-n redundant interconnects (where m is an integer greater than n), the first scan chain circuit includes m flip-flops, and the second scan chain circuit includes n flip-flops.

One or more embodiments may provide a semiconductor device, wherein the first test data includes m bits, and the second test data includes n bits.

One or more embodiments may provide a semiconductor device, wherein the first semiconductor die further includes a first test controller configured to: provide the first test data to the first scan chain circuit during the first test period; and provide the second test data to the second scan chain circuit during the second test period.

One or more embodiments may provide a semiconductor device, wherein the second scan chain circuit is configured to: receive, during the second test period, the second test data from a first test controller, and output the second test data to the first repair logic circuit; and receive, during a normal operating period, operating data from the first logic circuit, and output the operating data to the first repair logic circuit.

One or more embodiments may provide a semiconductor device, wherein the first scan chain circuit is configured to: output, during the first test period, the first test data received from the first test controller to the plurality of transmitting circuits; and output, during the second test period and the normal operating period, the second test data or the operating data received from the first repair logic circuit, to n transmitting circuits corresponding to the first repair path among the plurality of transmitting circuits (where n is an integer greater than or equal to 2).

One or more embodiments may provide a semiconductor device, wherein the first repair logic circuit includes a plurality of multiplexers, and the plurality of multiplexers are configured to, based on the defect information, selectively connect a plurality of second flip-flops of the second scan chain circuit to a plurality of first flip-flops of the first scan chain circuit.

One or more embodiments may provide a semiconductor device, wherein the second interface circuit of the second semiconductor die includes: a plurality of receiving circuits connected to the plurality of interconnects; a third scan chain circuit configured to receive signals from the plurality of receiving circuits; a second repair logic circuit configured to: set, based on the defect information, a second repair path; and output, along the second repair path, data input from the third scan chain circuit; and a fourth scan chain circuit configured to receive the data from the second repair logic circuit.

One or more embodiments may provide a semiconductor device, wherein the third scan chain circuit is configured to: receive, during the first test period, the first test data from the plurality of receiving circuits; and receive, during the second test period and a normal operating period, the second test data or operating data from n receiving circuits corresponding to the second repair path among the plurality of receiving circuits.

One or more embodiments may provide a semiconductor device, wherein the fourth scan chain circuit is configured to: receive, during the second test period, the second test data from the second repair logic circuit; and receive, during the normal operating period, the operating data from the second repair logic circuit and transmit the operating data to the second logic circuit.

One or more embodiments may provide a semiconductor device, wherein the second semiconductor die further includes a second test controller configured to: during the first test period: receive the first test data from the third scan chain circuit; and generate the defect information by comparing the first test data with first comparison data; and during the second test period: receive the second test data from the fourth scan chain circuit; and generate a test result by comparing the second test data with second comparison data.

One or more embodiments may provide a semiconductor device, wherein the first semiconductor die further includes a first non-volatile memory configured to store the defect information; and the second semiconductor die further includes a second non-volatile memory configured to store the defect information.

One or more embodiments may provide a semiconductor device, wherein the plurality of interconnects include n interconnects (where n is an integer greater than or equal to 2) and m-n redundant interconnects (where m is an integer greater than n), the first test data includes m bits, and the second test data includes n bits.

One or more embodiments may provide a semiconductor device, wherein the second interface circuit includes: a third scan chain circuit configured to transmit the first test data received via the plurality of interconnects to the second test controller; a second repair logic circuit configured to set, based on the first test result, a second repair path; and a fourth scan chain circuit configured to transmit the second test data received via the plurality of interconnects to the second test controller, the third scan chain circuit, and the second repair logic circuit.

One or more embodiments may provide a semiconductor device, wherein the first scan chain circuit and the third scan chain circuit each include m scan cells (where m is an integer greater than or equal to 3), wherein the second scan chain circuit and the fourth scan chain circuit each include n scan cells (where n is an integer less than m), and wherein the scan cell is configured to store and output 1 bit of data.

One or more embodiments may provide a semiconductor device, wherein the first semiconductor die and the second semiconductor die are stacked in a vertical direction.

One or more embodiments may provide a method, wherein the first scan chain circuit is connected to the third scan chain circuit via the first repair logic circuit, and wherein the second scan chain circuit is connected to the fourth scan chain circuit via the second repair logic circuit.

One or more embodiments may provide a method, wherein the first test includes: connecting, in series, a plurality of first scan cells of the first scan chain circuit; shifting the first test data into the plurality of first scan cells; and outputting the first test data from the plurality of first scan cells to the plurality of interconnects; and wherein the second test includes: connecting, in series, a plurality of third scan cells of the third scan chain circuit; shifting the second test data into the plurality of third scan cells; and outputting the second test data from the plurality of third scan cells to the first repair logic circuit.

While the disclosure has been particularly shown and described with reference to embodiments thereof, it will be understood that various changes in form and details may be made therein without departing from the spirit and scope of the following claims.

What is claimed is:

1. A three-dimensional (3D) integrated circuit comprising:
a first semiconductor die comprising:
a first logic circuit; and
a first interface circuit;
a second semiconductor die comprising:
a second logic circuit; and
a second interface circuit; and
a plurality of interconnects connected between the first semiconductor die and the second semiconductor die, the plurality of interconnects being configured to transmit signals,
wherein the first interface circuit comprises:
a plurality of transmitting circuits connected to the plurality of interconnects;
a first scan chain circuit configured to output, during a first test period, first test data to the plurality of transmitting circuits;
a first repair logic circuit configured to:
set, based on defect information generated by a first test result from the first test data, a first repair path configured to replace a defective interconnect among the plurality of interconnects with a non-defective redundant interconnect; and
output input data to the first scan chain circuit via the first repair path; and
a second scan chain circuit configured to output, during a second test period, second test data to the first repair path.

2. The 3D integrated circuit of claim 1, wherein the plurality of interconnects comprise n interconnects (where n is an integer greater than or equal to 2) and m-n redundant interconnects (where m is an integer greater than n),
the first scan chain circuit comprises m flip-flops, and
the second scan chain circuit comprises n flip-flops.

3. The 3D integrated circuit of claim 2, wherein the first test data comprises m bits, and
the second test data comprises n bits.

4. The 3D integrated circuit of claim 1, wherein the first semiconductor die further comprises a first test controller configured to:
provide the first test data to the first scan chain circuit during the first test period; and
provide the second test data to the second scan chain circuit during the second test period.

5. The 3D integrated circuit of claim 1, wherein the second scan chain circuit is configured to:
receive, during the second test period, the second test data from a first test controller, and
output the second test data to the first repair logic circuit; and
receive, during a normal operating period, operating data from the first logic circuit, and
output the operating data to the first repair logic circuit.

6. The 3D integrated circuit of claim 5, wherein the first scan chain circuit is configured to:
output, during the first test period, the first test data received from the first test controller to the plurality of transmitting circuits; and
output, during the second test period and the normal operating period, the second test data or the operating data received from the first repair logic circuit, to n transmitting circuits corresponding to the first repair path among the plurality of transmitting circuits (where n is an integer greater than or equal to 2).

7. The 3D integrated circuit of claim 1, wherein the first repair logic circuit comprises a plurality of multiplexers, and
the plurality of multiplexers are configured to, based on the defect information, selectively connect a plurality of second flip-flops of the second scan chain circuit to a plurality of first flip-flops of the first scan chain circuit.

8. The 3D integrated circuit of claim 1, wherein the second interface circuit of the second semiconductor die comprises:
a plurality of receiving circuits connected to the plurality of interconnects;
a third scan chain circuit configured to receive signals from the plurality of receiving circuits;
a second repair logic circuit configured to:
set, based on the defect information, a second repair path; and
output, along the second repair path, data input from the third scan chain circuit; and
a fourth scan chain circuit configured to receive the data from the second repair logic circuit.

9. The 3D integrated circuit of claim 8, wherein the third scan chain circuit is configured to:
receive, during the first test period, the first test data from the plurality of receiving circuits; and
receive, during the second test period and a normal operating period, the second test data or operating data from n receiving circuits corresponding to the second repair path among the plurality of receiving circuits.

10. The 3D integrated circuit of claim 9, wherein the fourth scan chain circuit is configured to:
receive, during the second test period, the second test data from the second repair logic circuit; and
receive, during the normal operating period, the operating data from the second repair logic circuit and transmit the operating data to the second logic circuit.

11. The 3D integrated circuit of claim 10, wherein the second semiconductor die further comprises a second test controller configured to:
during the first test period:
receive the first test data from the third scan chain circuit; and
generate the defect information by comparing the first test data with first comparison data; and
during the second test period:
receive the second test data from the fourth scan chain circuit; and
generate a test result by comparing the second test data with second comparison data.

12. The 3D integrated circuit of claim 1, wherein the first semiconductor die further comprises a first non-volatile memory configured to store the defect information; and
the second semiconductor die further comprises a second non-volatile memory configured to store the defect information.

13. A semiconductor device comprising:
a first semiconductor die comprising:
a first interface circuit; and
a first test controller;
a second semiconductor die comprising:
a second interface circuit; and
a second test controller; and
a plurality of interconnects connected to the first semiconductor die and the second semiconductor die, the plurality of interconnects being configured to transmit signals,
wherein the first interface circuit comprises:
a first scan chain circuit configured to:
receive first test data from the first test controller; and
output the first test data;
a first repair logic circuit configured to:
set, based on a first test result from the first test data, a first repair path configured to replace a defective interconnect among the plurality of interconnects using a non-defective redundant interconnect; and
a second scan chain circuit configured to:
receive second test data from the first test controller;
detect, based on the second test data, a defect in a signal path; and
output the second test data,
wherein the signal path comprises:
the first repair path;
the first scan chain circuit; and
interconnects corresponding to the first repair path among the plurality of interconnects.

14. The semiconductor device of claim 13, wherein the plurality of interconnects comprise n interconnects (where n is an integer greater than or equal to 2) and m-n redundant interconnects (where m is an integer greater than n),
the first test data comprises m bits, and
the second test data comprises n bits.

15. The semiconductor device of claim 13, wherein the second interface circuit comprises:
a third scan chain circuit configured to transmit the first test data received via the plurality of interconnects to the second test controller;
a second repair logic circuit configured to set, based on the first test result, a second repair path; and
a fourth scan chain circuit configured to transmit the second test data received via the plurality of interconnects to the second test controller, the third scan chain circuit, and the second repair logic circuit.

16. The semiconductor device of claim 15, wherein the first scan chain circuit and the third scan chain circuit each comprise m scan cells (where m is an integer greater than or equal to 3),
wherein the second scan chain circuit and the fourth scan chain circuit each comprise n scan cells (where n is an integer less than m), and
wherein the scan cell is configured to store and output 1 bit of data.

17. The semiconductor device of claim 13, wherein the first semiconductor die and the second semiconductor die are stacked in a vertical direction.

18. A method of testing a three-dimensional (3D) integrated circuit comprising a first semiconductor die and a second semiconductor die connected to each other by a plurality of interconnects, the method comprising:
performing a first test by transmitting, via a first test path comprising the plurality of interconnects, first test data from a first scan chain circuit of the first semiconductor die to a second scan chain circuit of the second semiconductor die;
setting, based on defect information generated by results of the first test, a repair path that comprises:
a first repair logic circuit of the first semiconductor die; and
a second repair logic circuit of the second semiconductor die,
wherein the repair path is configured to replace a defective interconnect among the plurality of interconnects with a non-defective redundant interconnect; and
performing a second test by transmitting, via a second test path comprising the repair path and interconnects corresponding to the repair path among the plurality of interconnects, second test data from a third scan chain circuit of the first semiconductor die to a fourth scan chain circuit of the second semiconductor die.

19. The method of claim 18, wherein the first scan chain circuit is connected to the third scan chain circuit via the first repair logic circuit, and
wherein the second scan chain circuit is connected to the fourth scan chain circuit via the second repair logic circuit.

20. The method of claim 18, wherein the first test comprises:
connecting, in series, a plurality of first scan cells of the first scan chain circuit;
shifting the first test data into the plurality of first scan cells; and
outputting the first test data from the plurality of first scan cells to the plurality of interconnects; and
wherein the second test comprises:
connecting, in series, a plurality of third scan cells of the third scan chain circuit;
shifting the second test data into the plurality of third scan cells; and
outputting the second test data from the plurality of third scan cells to the first repair logic circuit.
